(19) United States
(12) Patent Application Publication
(10) Pub. No.: US 2024/0395847 A1
(43) Pub. Date: Nov. 28, 2024

(54) OPTOELECTRONIC DEVICE HAVING A PHOTODIODE INCLUDING A QUANTUM DOT MATERIAL

(71) Applicant: Taiwan semiconductor Manufacturing Company, Ltd., Hsinchu (TW)

(72) Inventors: Chun-Hao LIN, Tainan City (TW); Yun-Wei CHENG, Taipei City (TW); Kuo-Cheng LEE, Tainan City (TW)

(21) Appl. No.: 18/324,580

(22) Filed: May 26, 2023

(51) Int. Cl. H01L 27/146

(52) U.S. Cl. CPC H01L 27/14645; H01L 27/14621; H01L 27/14632; H01L 27/14685; H01L 27/14687

(57) ABSTRACT

Some implementations described herein include a complementary metal oxide semiconductor image sensor device for an image detection system that is used in a low-light environment. The complementary metal-oxide semiconductor image sensor device includes a photodiode for detecting near infrared and/or short-wave infrared light waves. The photodiode includes a layer of a quantum dot material and a transparent electrode over the layer of the quantum dot material. In addition to the photodiode having an improved quantum efficiency relative to a silicon-based photodiode, the photodiode is integrated within a color filter array structure to obviate the need for separate a separate visible light complementary metal-oxide semiconductor image sensor device in the image detection system.

### BACKGROUND

A complementary metal oxide semiconductor (CMOS) image sensor may include a plurality of pixel sensors. A pixel sensor of the CMOS image sensor may include a transfer transistor, which may include a photodiode configured to convert photons of incident light into a photocurrent of electrons and a transfer gate configured to control the flow of the photocurrent between the photodiode and a drain region. The drain region may be configured to receive the photocurrent such that the photocurrent can be measured and/or transferred to other areas of the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of an implementation of an example optoelectronic device including a pixel sensor array described herein.

FIG. 3 is a diagram of an example optoelectronic device described herein.

FIGS. 4A-4O are diagrams of an example series of operations for forming the optoelectronic device of FIG. 3

FIG. 5 is a diagram of an example optoelectronic device described herein.

FIG. 6 is a diagram of an example optoelectronic device described herein.

FIGS. 7A-7I are diagrams of an example implementation of forming the optoelectronic device of FIG. 5.

FIG. 8 is a diagram of example components of one or more devices of FIG. 1 described herein.

FIG. 9 is a flowchart of an example process associated with forming an optoelectronic device having a photodiode including a quantum dot material.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a complementary metal oxide semiconductor (CMOS) image sensor (CIS) device utilizes light-sensitive CMOS circuitry to convert light energy into electrical energy. In such cases, the light-sensitive CMOS circuitry includes a photodiode formed in a silicon substrate. As the photodiode is exposed to light, an electrical charge is induced in the photodiode (referred to as a photocurrent). Further, and in such cases, a switching transistor coupled to the photodiode is used to sample the charge of the photodiode. Colors are determined by placing filters over the light-sensitive CMOS circuitry.

A CIS device in a low-lighting application includes dedicated pixels having silicon-based photodiodes for absorbing reflected near infrared (NIR) light waves or short-wave infrared (SWIR) light waves. Such silicon-based photodiodes may have a low quantum efficiency (QE) performance. Solutions to improve the NIR/SWIR QE performance of the silicon-based photodiodes (e.g., high absorption (HA) structures, deep trench isolation (DTI) structures, and/or thicker silicon) add complexities to manufacturing of the CIS device and decrease a yield of the CIS device relative to another CIS device not including such solutions. Furthermore, the silicon-based photodiodes for absorbing NIR/SWIR light waves consume additional space within the CIS device.

Some implementations described herein include a CIS device for an image detection system that is used in a low-light environment. The CIS device includes a photodiode for detecting NIR and/or SWIR light waves. The photodiode includes a layer of a quantum dot material and a transparent electrode over the layer of the quantum dot material. In addition to the photodiode having an improved QE relative to a silicon-based photodiode, the photodiode is integrated within a color filter array structure to obviate the need for separate a separate visible light (VIS) CIS device in the image detection system.

In this way, a performance (e.g., an NIR/SWIR QE) of a CIS device including the photodiode is improved relative to another CIS device not including the photodiode. Improving the performance of the CIS device increases a manufacturing yield of the CIS device to a particular performance threshold. By increasing the manufacturing yield and obviating the need for a separate VIS device, an amount of resources required to support a market that consumes a volume of the image detection system having NIR/SWIR and VIS light detection capabilities (e.g. semiconductor manufacturing tools, labor, raw materials, and/or computing resources) is reduced.

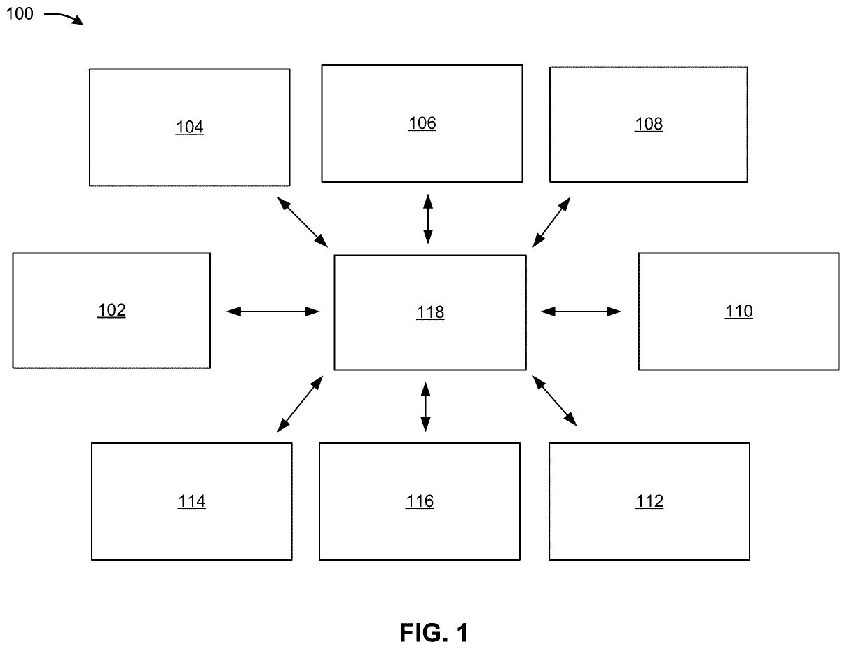

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, an ion implantation tool 114, a bonding tool 116, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The bonding tool 116 is a semiconductor processing tool that is capable of bonding two or more wafers (or two or more semiconductor substrates, or two or more semiconductor devices) together. For example, the bonding tool 116 may include a eutectic bonding tool that is capable of forming a eutectic bond between two or more wafers together. In these examples, the bonding tool may heat the two or more wafers to form a eutectic system between the materials of the two or more wafers. As another example, the bonding tool 116 may include a hybrid bonding tool, a direct bonding tool, and/or another type of bonding tool.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

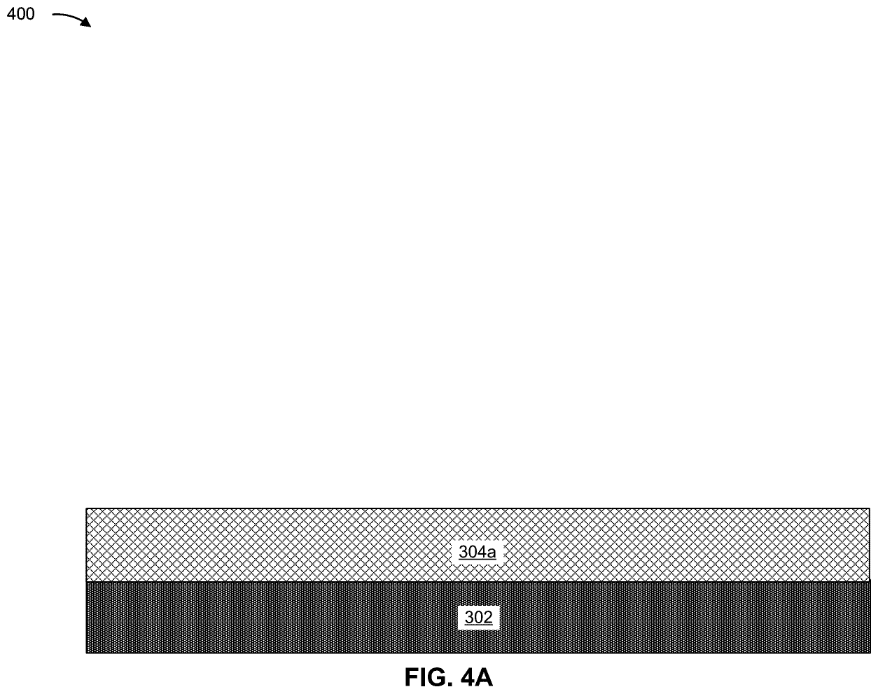

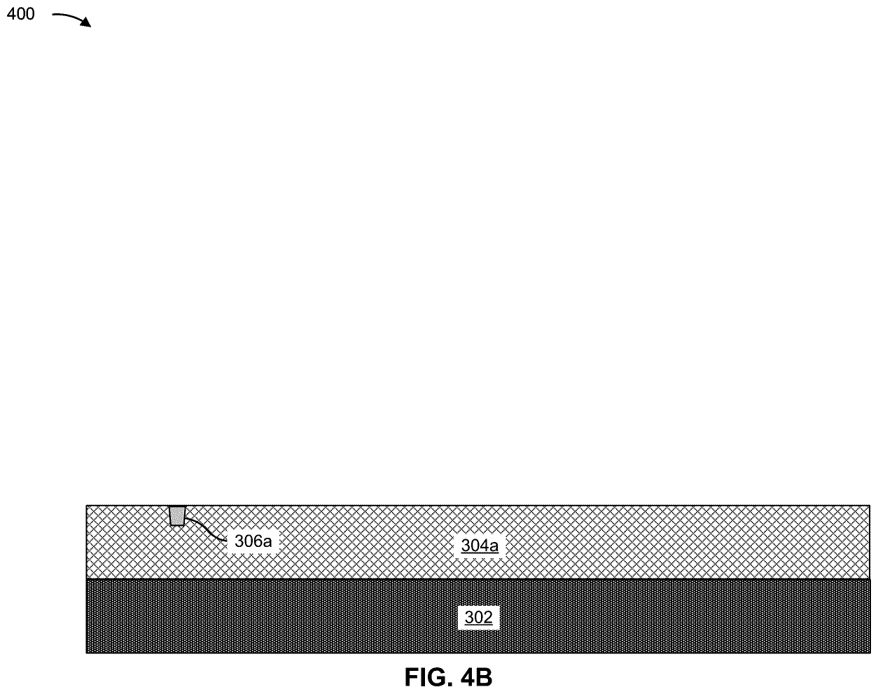

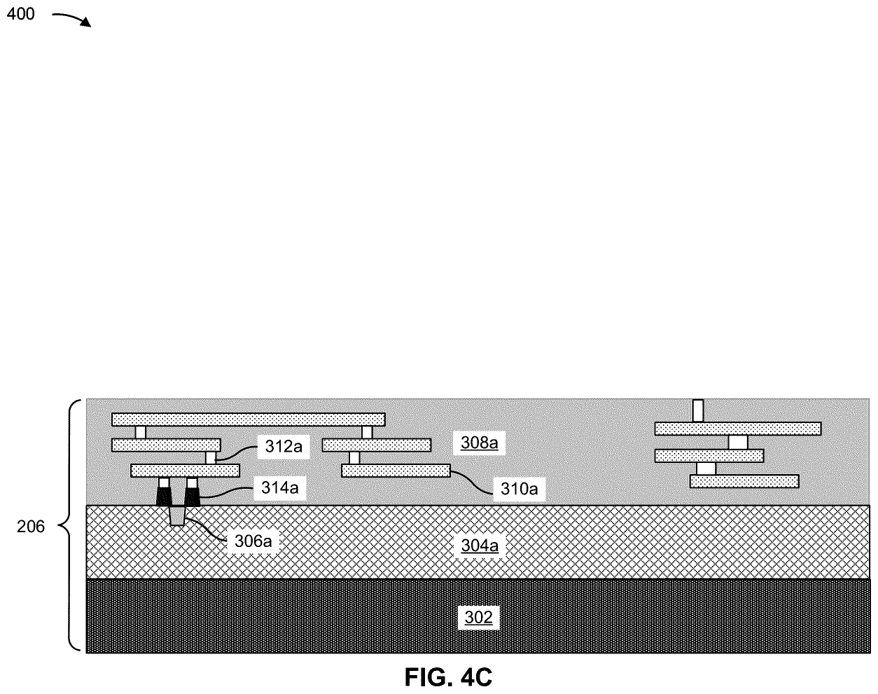

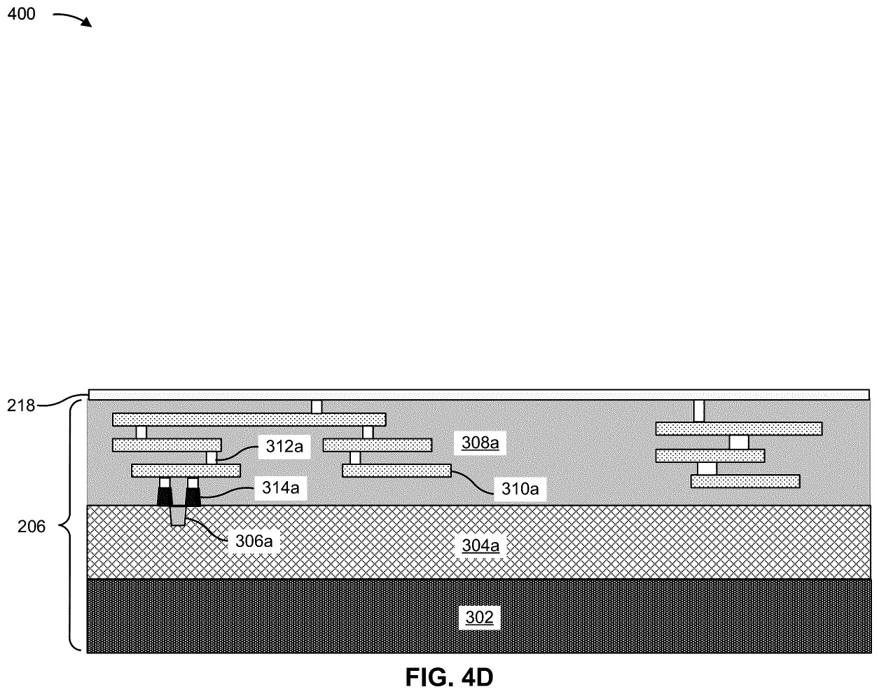

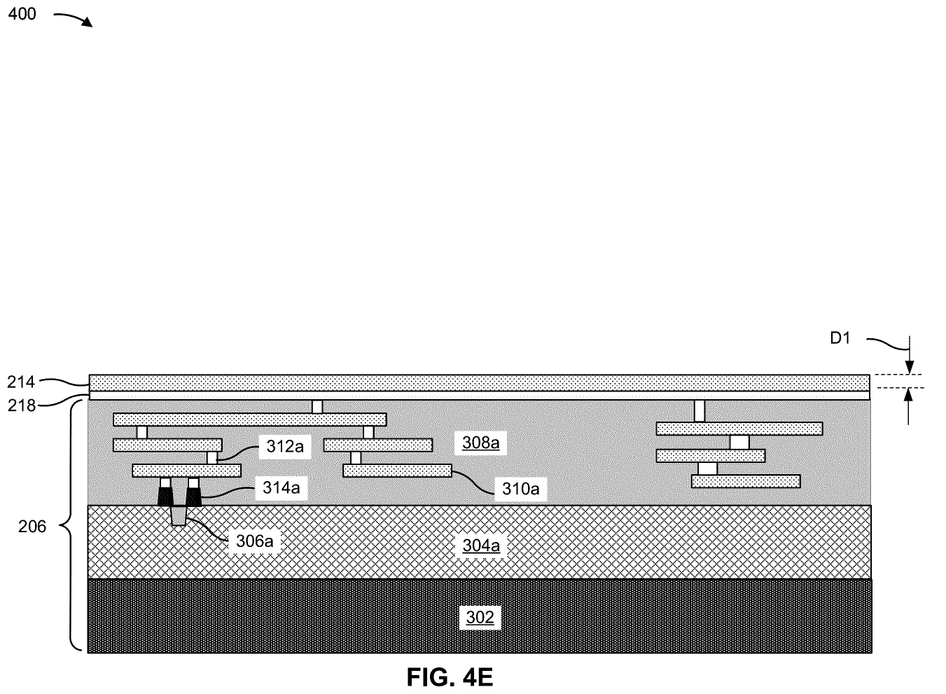

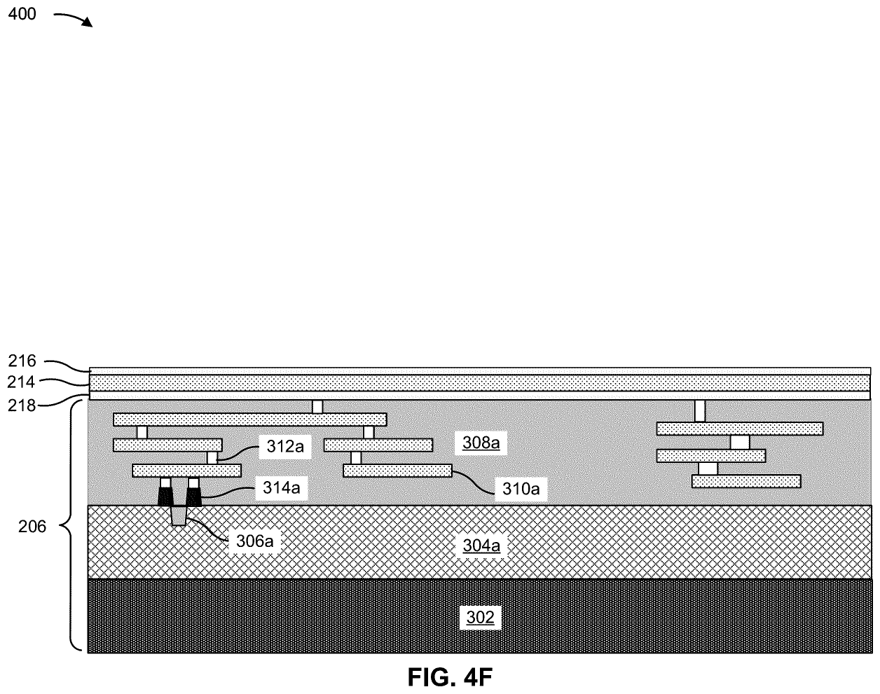

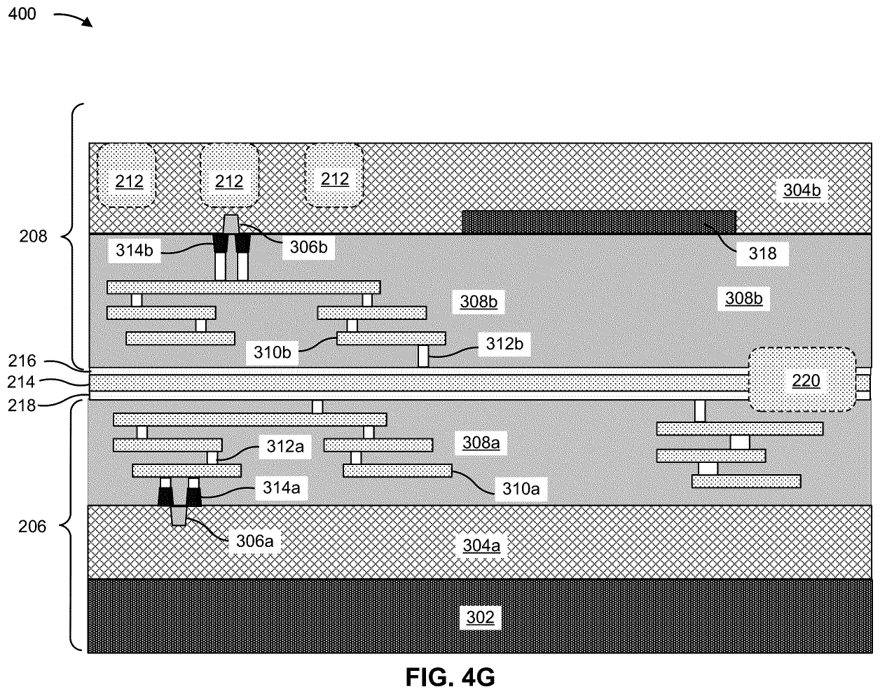

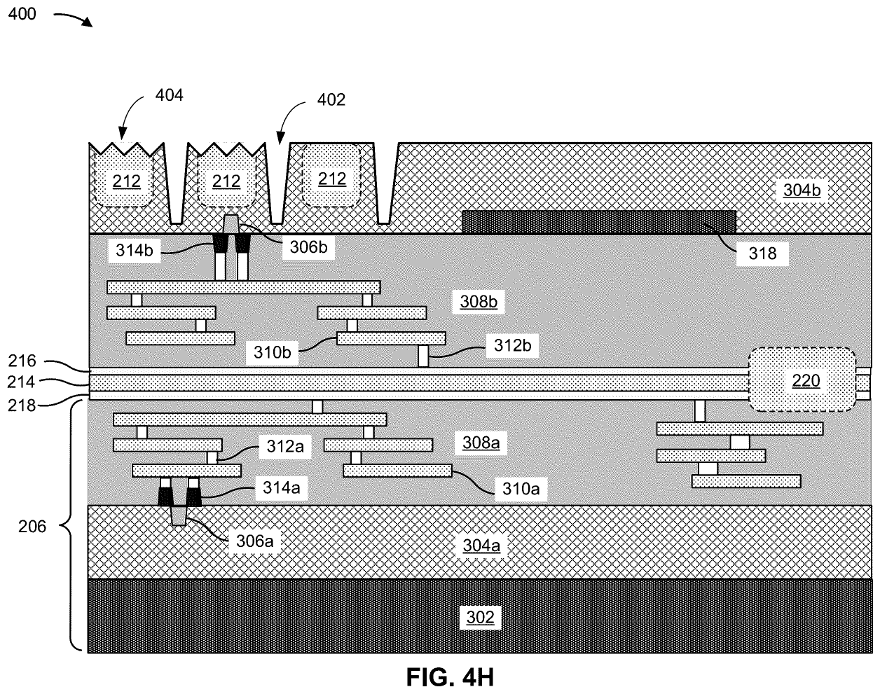

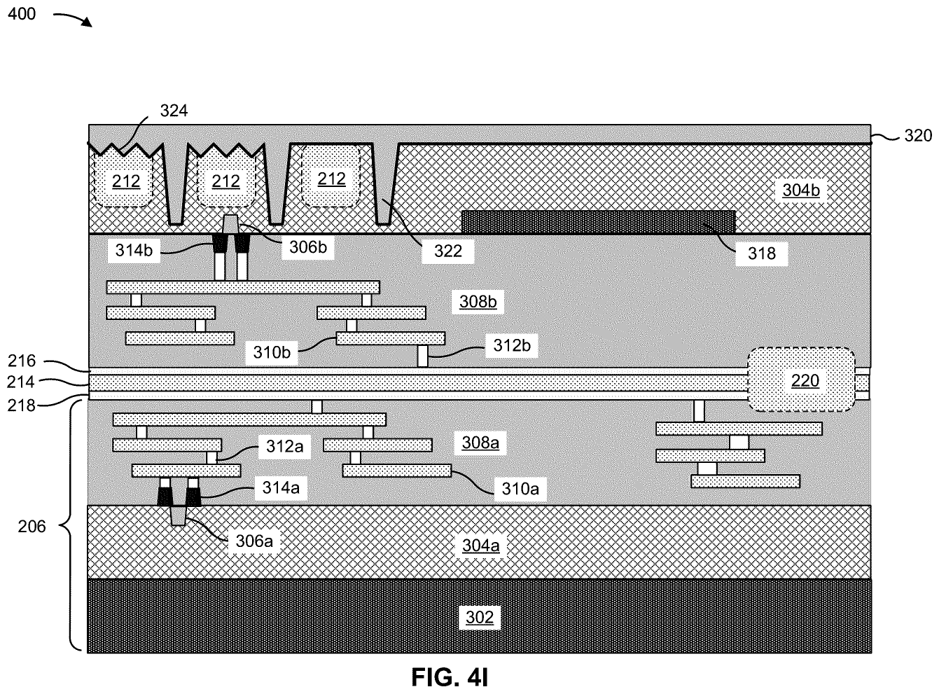

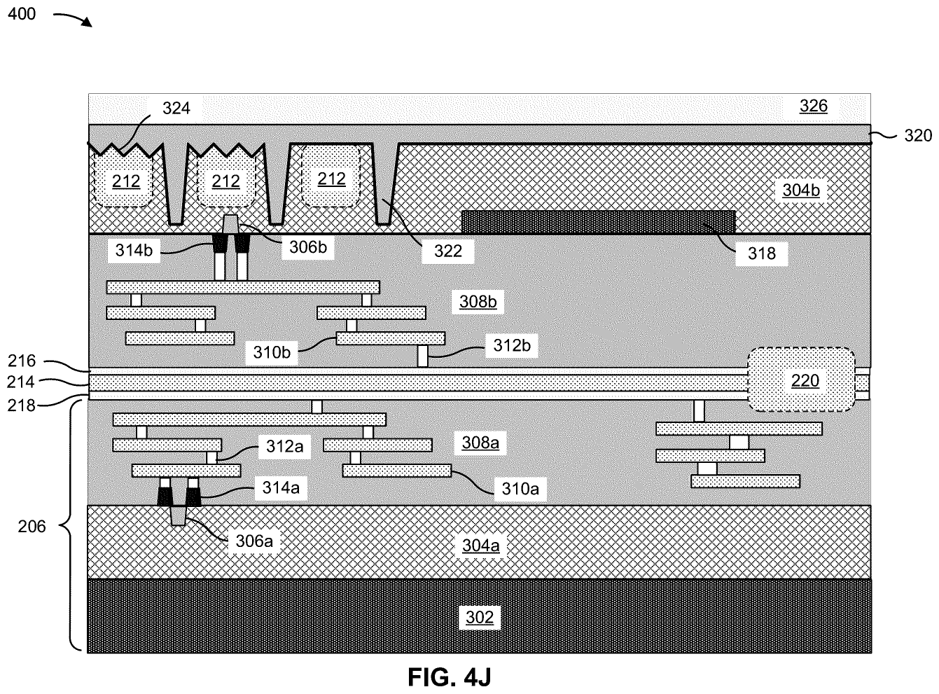

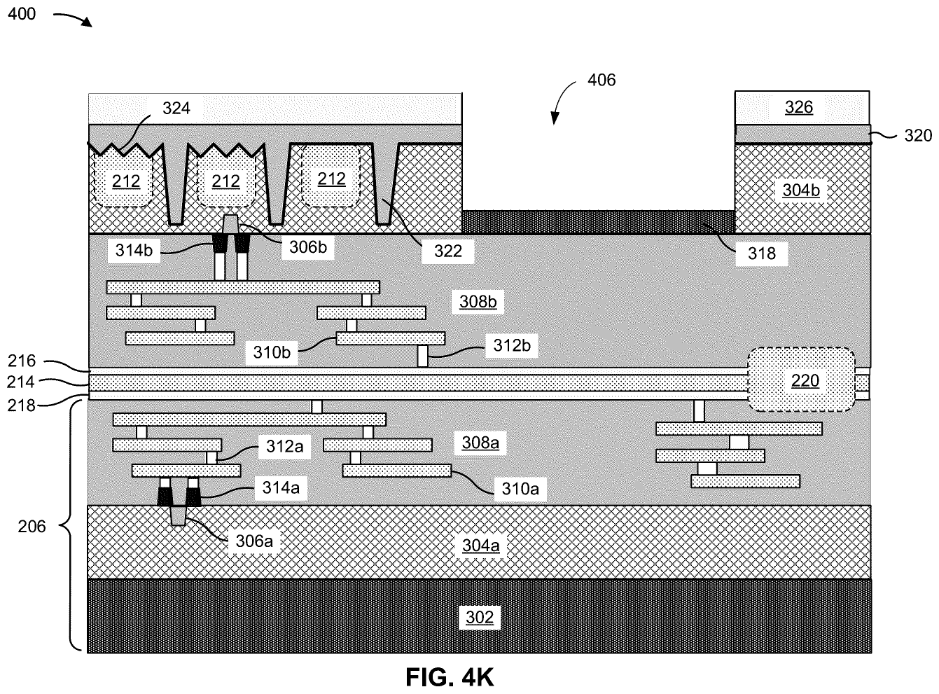

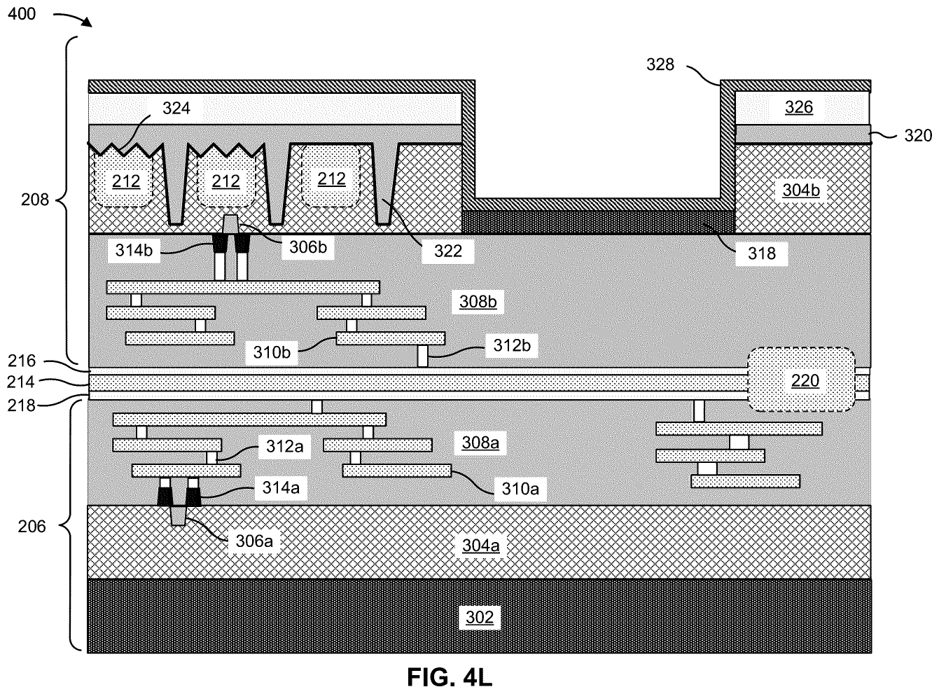

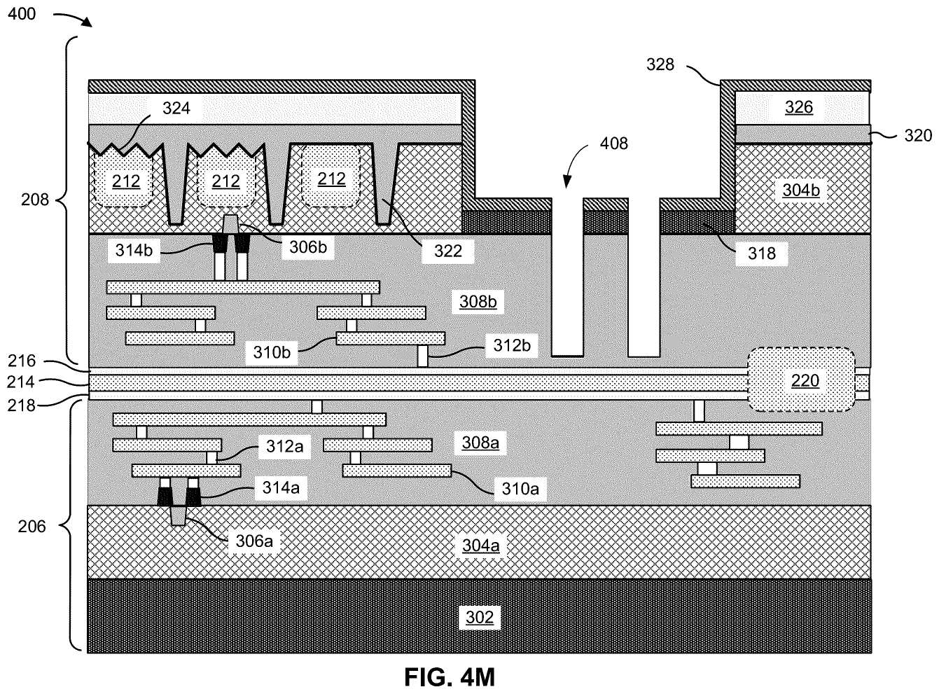

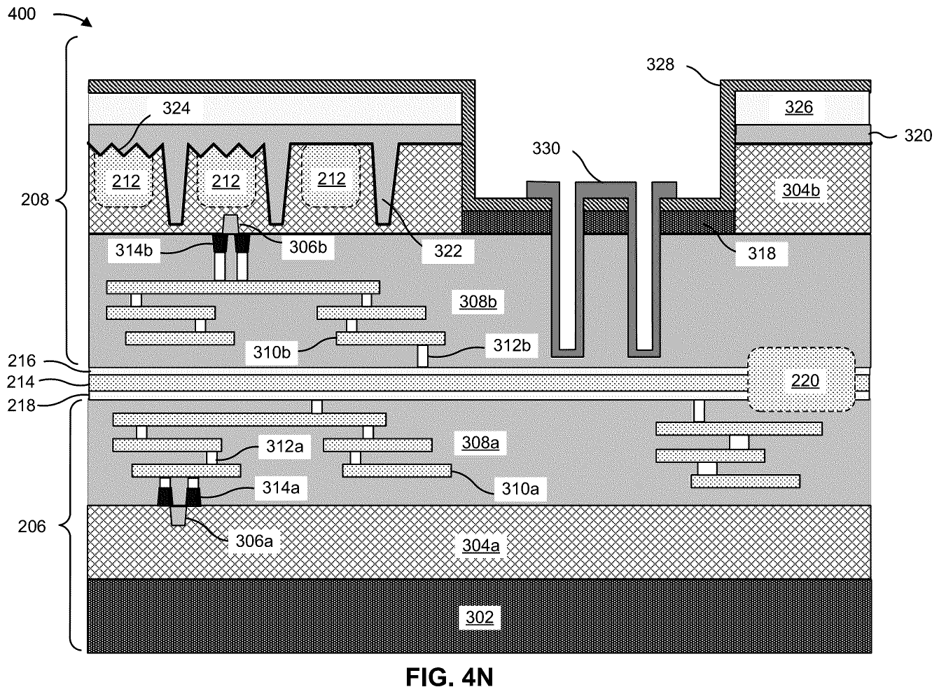

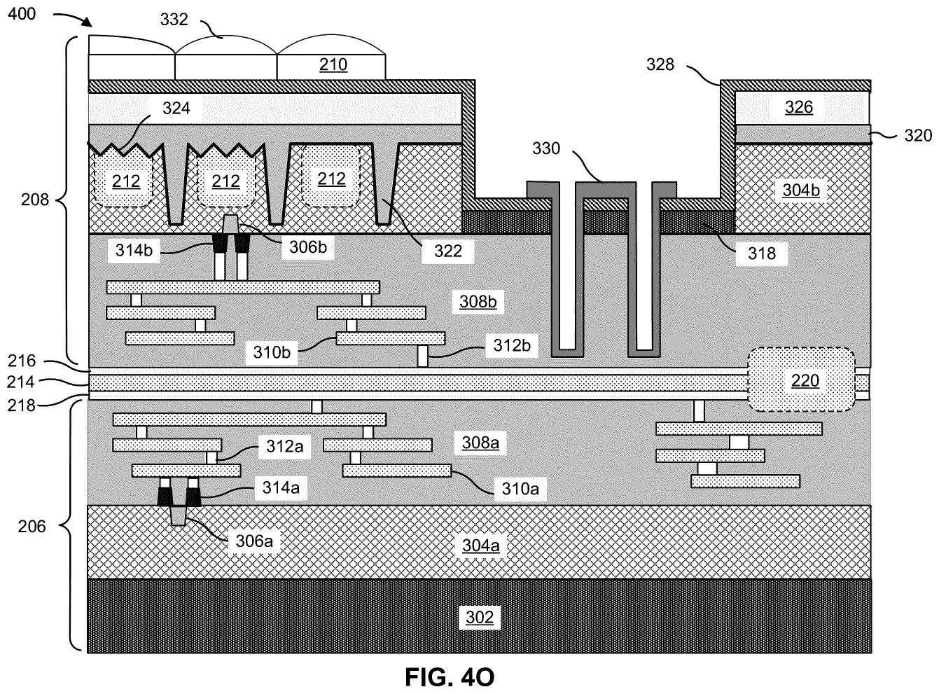

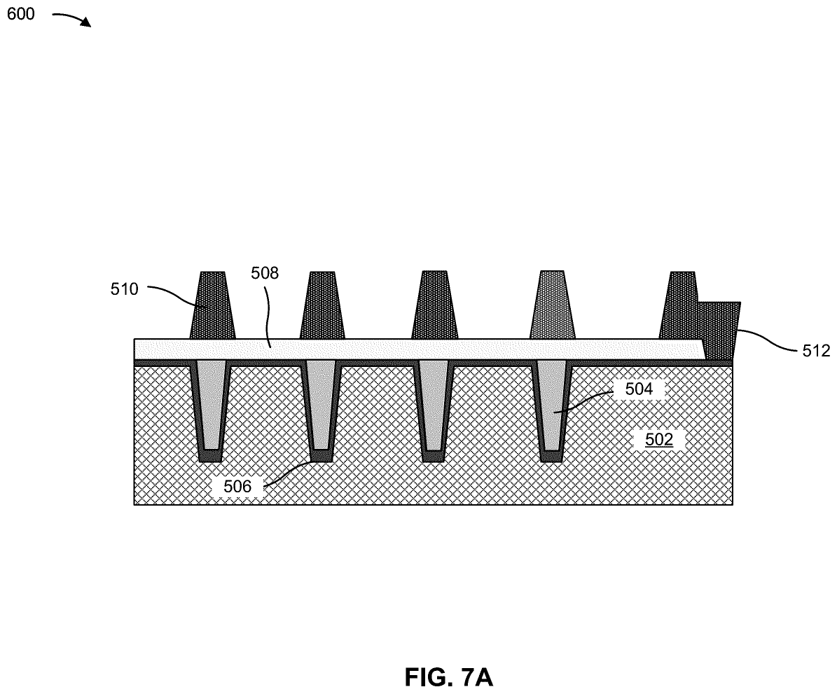

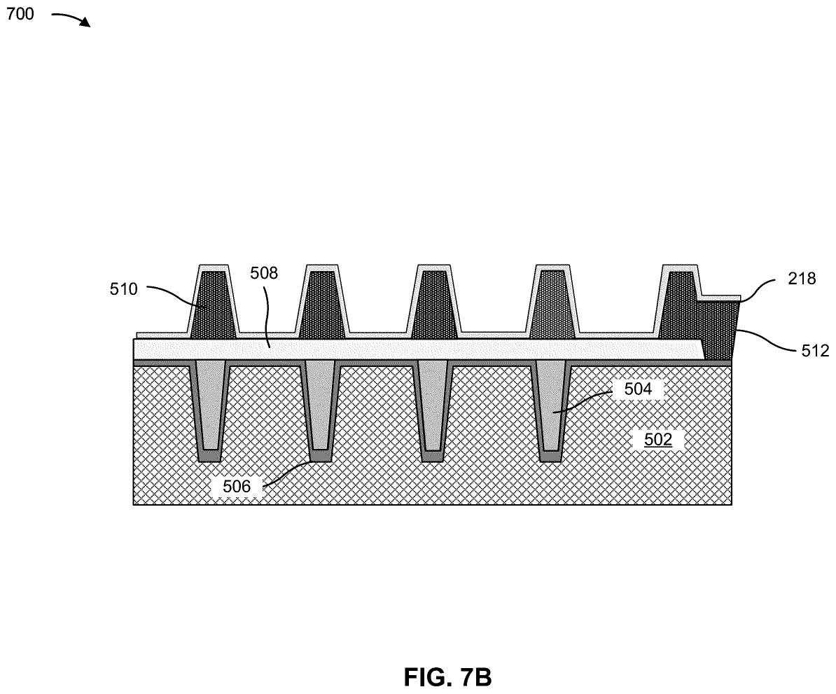

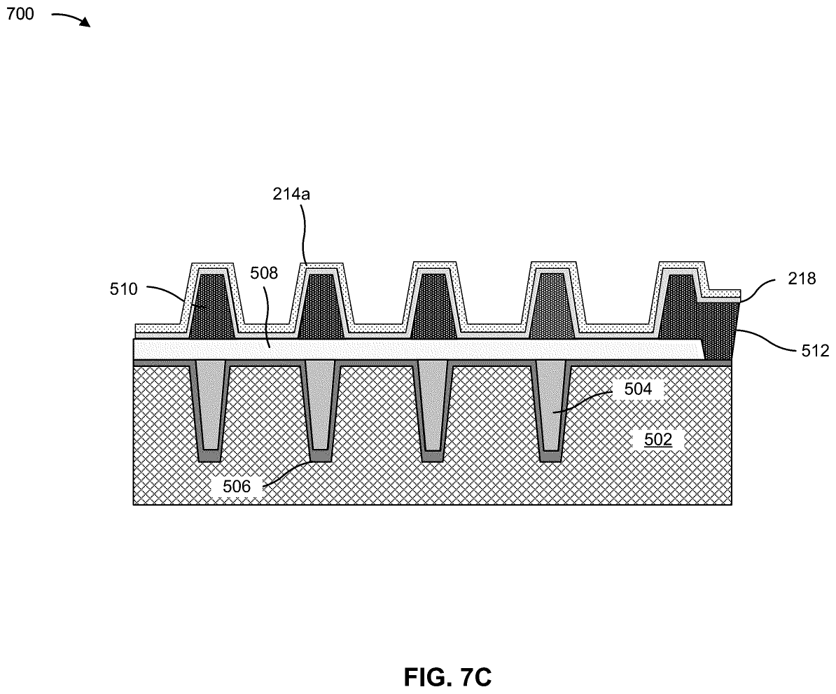

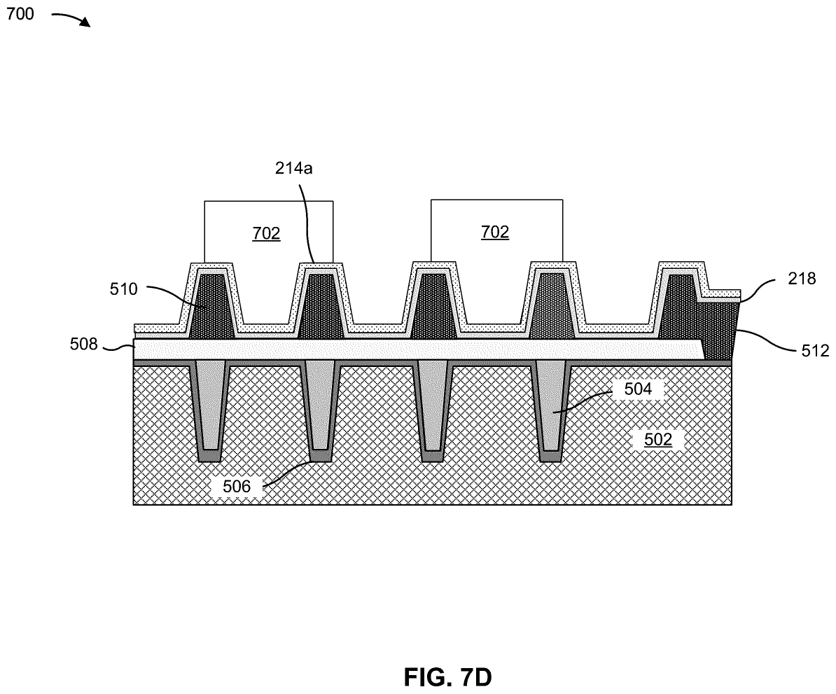

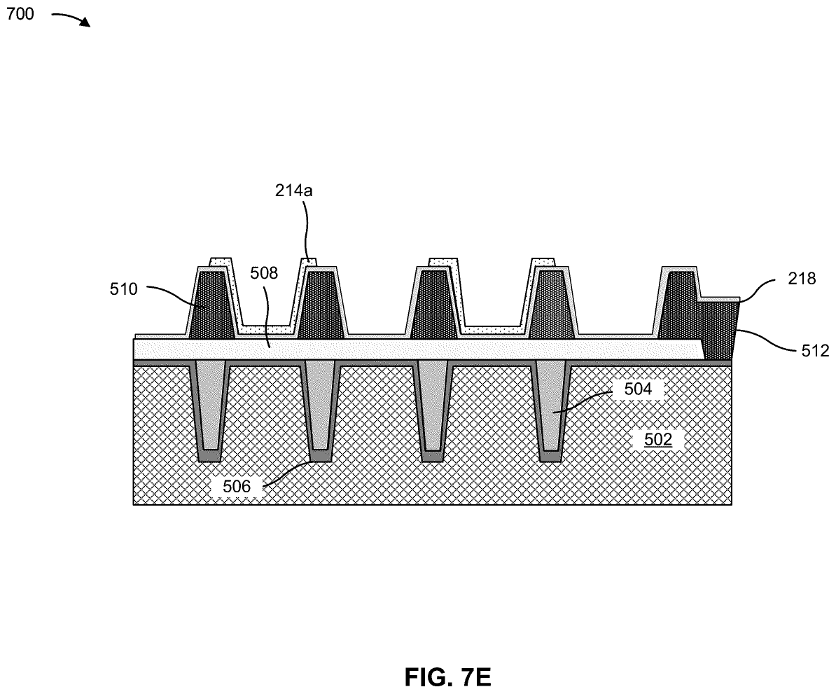

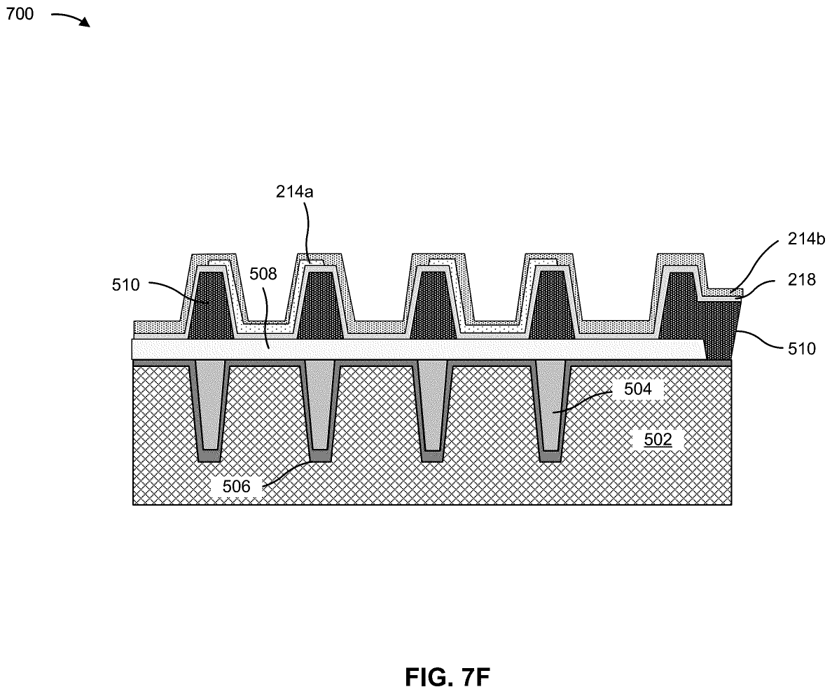

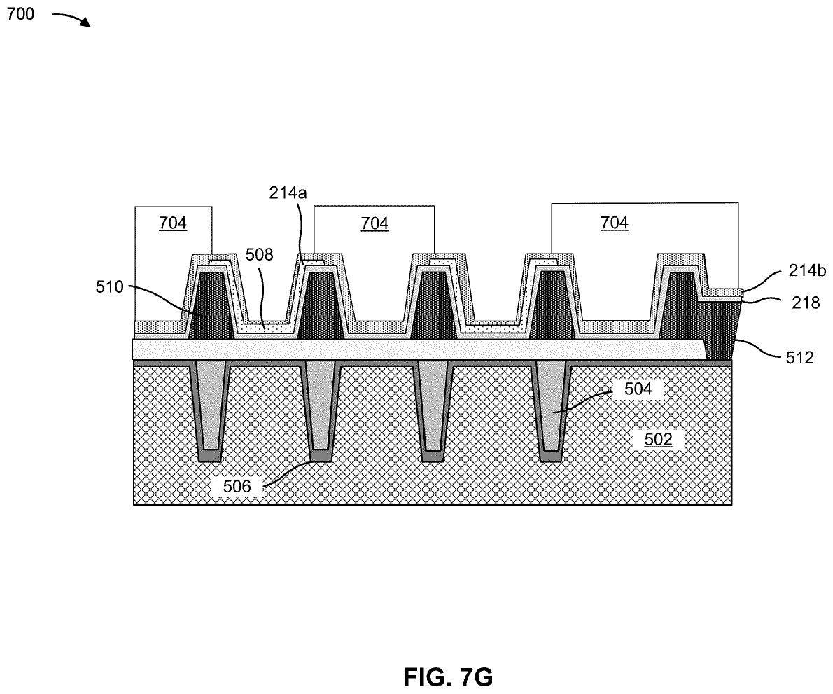

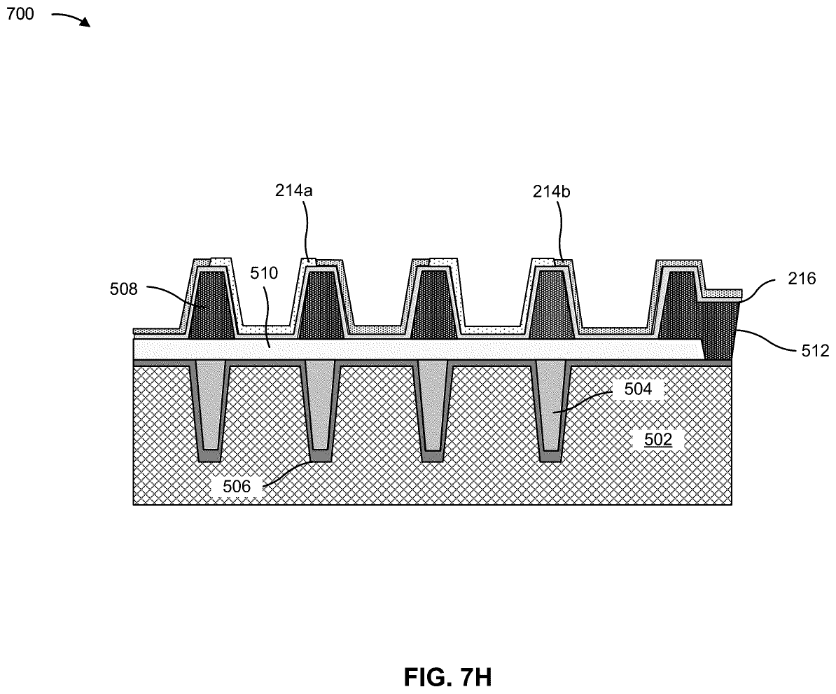

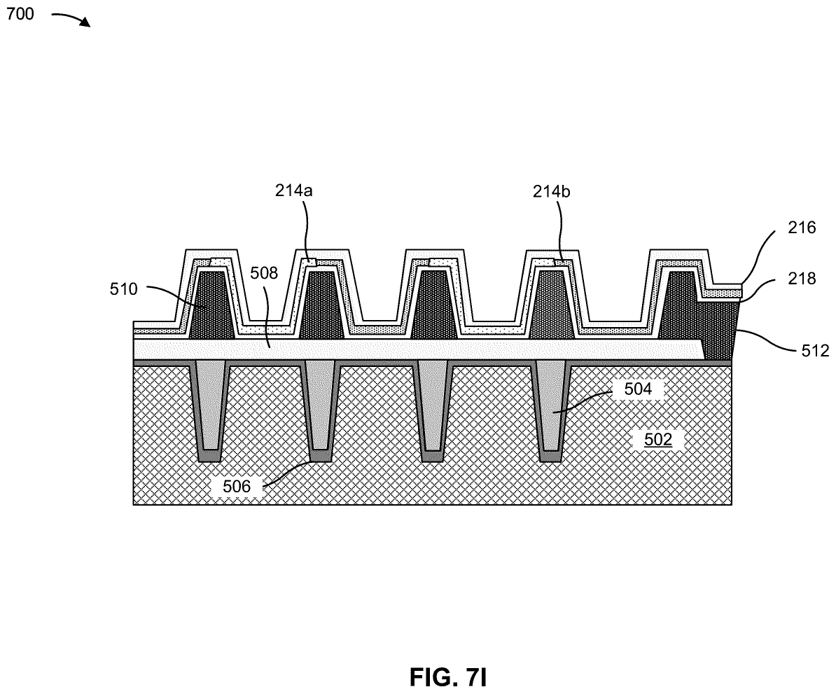

One or more of the semiconductor processing tools 102-116 and/or the wafer/die transport tool 118 may perform a series of one or more semiconductor processing operations described herein. In some implementations, and as an example, the series of one or more semiconductor processing operations includes forming a layer of a first conductive material on a surface. The series of one or more semiconductor processing operations includes forming a layer of a quantum dot material on the layer of the first conductive material. The series of one or more semiconductor processing operations includes forming a layer of a second conductive material on the layer of the quantum dot material, where the second conductive material is transmissive to near infrared light waves or transmissive to short-wave infrared light waves. In some implementations, one or more of the semiconductor processing operations performed by the semiconductor processing tools 102-116 and/or the wafer/die transport tool 118 may correspond to one or more semiconductor processing operations described in connection with FIGS. 4A-4O, FIGS. 7A-7I, and elsewhere herein, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

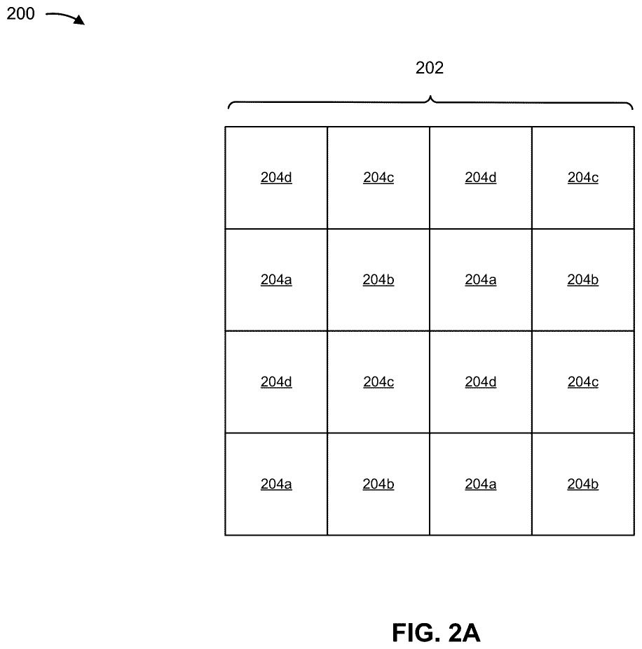

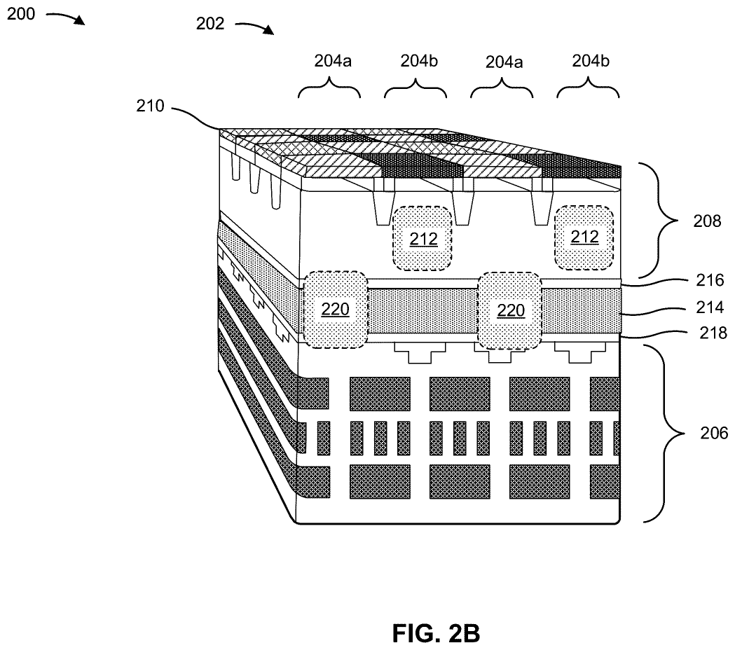

FIGS. 2A and 2B are diagrams of an implementation of an example optoelectronic device 200 including a pixel sensor array 202 described herein. The optoelectronic device 200 may be configured to be deployed in various implementations, such as digital cameras, video recorders, night-vision cameras, automotive sensors and cameras, and/or other types of low-light implementations.

As shown in the top-down view of FIG. 2A, the optoelectronic device 200 includes the pixel sensor array 202. The pixel sensor array 202 may include pixel sensors 204a-204d. As further shown in FIG. 2A, the pixel sensors 204a-204d are arranged in a grid. In some implementations, the pixel sensors 204a-204d are square-shaped (as shown in the example in FIG. 2). In some implementations, the pixel sensors 204a-204d include other shapes such as circle shapes, octagon shapes, diamond shapes, and/or other shapes.

The pixel sensor array 202 may include a filter array that causes the pixels sensors 204a-204d to sense and/or accumulate incident light (e.g., light directed toward the pixel sensor array 202) of particular wavelengths. For example, the pixel sensor 204a may include a filter that limits the pixel sensor 204a to absorbing and accumulating photons of incident light corresponding to NIR light (e.g., electromagnetic waves having a wavelength in a range of approximately 800 nanometers to approximately 2500 nanometers) or shortwave infrared (SWIR) light (e.g., electromagnetic waves having a wavelength in a range of approximately 900 nanometers to approximately 2500 nanometers). Additionally, or alternatively, the pixel sensor 204b may include a color filter that limits the pixel sensor 204b to absorbing and accumulating photons of incident light corresponding to red visible light (e.g., electromagnetic waves having a wavelength in a range of approximately 620 nanometers to approximately 850 nanometers). Additionally, or alternatively, the pixel sensor 204c may include a color filter that limits the pixel sensor 204c to absorbing and accumulating photons of incident light corresponding to green visible light (e.g., electromagnetic waves having a wavelength in a range of approximately 490 nanometers to approximately 570 nanometers). Additionally, or alternatively, the pixel sensor 204d may include a color filter that limits the pixel sensor 204d to absorbing and accumulating photons of incident light corresponding to blue visible light (e.g., electromagnetic waves having a wavelength in a range of approximately 450 nanometers to approximately 490 nanometers). Photodiodes for each pixel sensor 204a-204d of the pixel sensor array 202 may generate a charge representing the intensity or brightness of the incident light (e.g., a greater amount of charge may correspond to a greater intensity or brightness, and a lower amount of charge may correspond to a lower intensity or brightness).

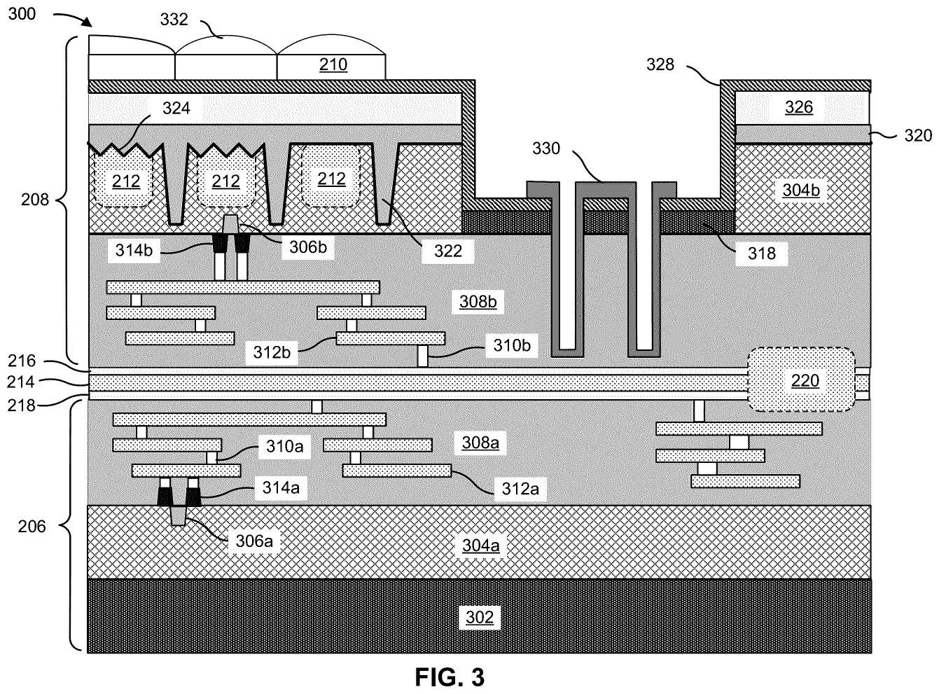

As shown in the isometric view of FIG. 2B, the optoelectronic device 200 may include an application-specific integrated circuit device 206 (ASIC device) joined with a system-on-chip integrated circuit device 208 (SoC device). As described in greater detail in connection with FIGS. 3-4O and elsewhere herein, the ASIC device 206 may include a combination of metallization layers and integrated circuitry (e.g., transistor structures).

In FIG. 2B, the SoC device 208 includes a filter layer 210 (e.g., a filter array including visible, color light filters and NIR filters) and photodiodes 212. In some implementations, the photodiodes 212 are organic photodiodes formed in a semiconductor layer of the SoC device 208 (e.g., regions including a p-type dopant or an n-type dopant within a layer of a semiconductor material in the SoC device 208). The photodiodes 212 are below the visible color light filters of the filter layer 210.

As further shown in FIG. 2B, a multi-layer structure (e.g., an interface structure) including a layer of a quantum dot material 214, a layer of a conductive material 216 (e.g., a top electrode layer), and a layer of a conductive material 218 (e.g., a bottom electrode layer), is between the ASIC device 206 and the SoC device 208. A photodiode 220 (e.g., a photodiode included as part of the multi-layer structure, including portions of the layer of the quantum dot material 214, portions the layer of the conductive material 216, and portions of the layer of the conductive material 218) is below NIR filters of the filter layer 210.

The layer of quantum dot material 214 may include quantum dots to form a p-n junction between the layer of the conductive material 216 and the layer of the conductive material 218 (e.g., between electrodes). The quantum dots may include a lead sulfide core (PbS), a cadmium selenide core (CdSe), a cadmium telluride core (CdTe), an indium phosphide core, and/or a zinc selenide core (ZnSe), among other examples.

A photodiode made using the layer of quantum dot material 214 utilizes unique properties of quantum dots to enhance its performance. Quantum dots are nanoscale particles made of semiconductor materials, such as cadmium selenide or indium arsenide. The quantum dots absorb photons of light, creating excitons that separate into an electron-hole pair when an electric field is applied. In a photodiode made using quantum dot material, the quantum dots form a p-n junction layer between two electrodes. When light enters the device and is absorbed by the quantum dots, it creates electron-hole pairs that the electric field at the p-n junction separates. The resulting electrical current indicates the intensity of the incident light.

Photodiodes made using quantum dots have several advantages over traditional photodiodes. Photodiodes made using quantum dots detect low levels of light with high absorption efficiency, and spectral sensitivity of the photodiodes is tunable by adjusting the size and composition of the quantum dots. Additionally, photodiodes made using quantum dots are more accessible for use in a wide range of applications because the photodiodes can be fabricated using low-cost solution-based methods. Such applications include optical communication, sensing, and imaging.

The layer of the conductive material 216 may include a material that is transmissive to electromagnetic waves corresponding to NIR light waves. For example, the layer of the conductive material 216 may include a tin oxide material (SnO₂) including an indium dopant (In), a tin oxide material including an antimony dopant (Ps), and/or a tin oxide material including a fluorine dopant (Fl). In some implementations, the layer of the conductive material 218 includes a same type of material as the layer of the conductive material 216 (e.g., a layer of the material that is transmissive to electromagnetic waves corresponding to NIR light waves). Alternatively, the layer the conductive material 218 may include another conductive material (e.g., aluminum (Al), titanium (Ti), or copper (Cu)) that is not transmissive to electromagnetic waves corresponding to NIR light waves.

As indicated above, FIGS. 2A and 2B are provided as an example. Other examples may differ from what is described with regard to FIGS. 2A and 2B.

FIG. 3 is a diagram of an example optoelectronic device 300 described herein. The optoelectronic device 300 in the side view of FIG. 3 may include one or more portions of the optoelectronic device 200 of FIGS. 2A and 2B, including the ASIC device 206 and the SoC device 208 over the ASIC device 206.

As shown in FIG. 3, the ASIC device 206 includes a substrate 302. The substrate 302 may include a semiconductor material such as a silicon material. The ASIC device 206 further includes a layer of a semiconductor material 304a over the substrate 302. The layer of the semiconductor material 304a may include a semiconductor material such as a silicon (Si). In some implementations, and as shown in FIG. 3, the layer of the semiconductor material 304a includes portions of transistor circuitry. For example, the layer of the semiconductor material 304a may include a gate structure 306a of transistor circuitry.

As further shown in FIG. 3, the ASIC device 206 may include a dielectric region 308a above and/or on the substrate 302. The dielectric region 308a (e.g., an intermetal dielectric region) may include one or more layers of dielectric material (e.g., a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), carbon doped silicon oxide, or another dielectric material). Various interconnect structures 310a (e.g., vertical interconnect access structures, or vias) and metallization layers 312a may be formed in and/or in between the layers of the dielectric region 308a. The metallization layers 312a may include bonding pads, conductive lines, and/or other types of conductive structures that electrically connect the various regions of the ASIC device 206 and/or electrically connect the various regions of the ASIC device 206 one or more external devices and/or external packaging. The interconnect structures 310a and metallization layers 312a may be referred to as a BEOL metallization stack, and may include a conductive material, such as gold, copper, silver, cobalt, tungsten, a metal alloy, or a combination thereof, among other examples.

In some implementations, portions of transistor circuitry may be included in the dielectric region 308a. For example, one or more source/drain regions 314a (e.g., a doped semiconductor material such as silicon (Si) or silicon germanium (SiGe)) may be included in the dielectric region 308a. The source/drain regions 314a may be connected with the gate structure 306a.

As shown in FIG. 3, the SoC device 208 includes a dielectric region 308b. The dielectric region 308b (e.g., an intermetal dielectric region) may include one or more layers of dielectric material (e.g., a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), carbon doped silicon oxide, or another dielectric material). Various interconnect structures 310b (e.g., vertical interconnect access structures, or vias) and metallization layers 312b may be formed in and/or in between the layers of the dielectric region 308b. The metallization layers 312b may include bonding pads, conductive lines, and/or other types of conductive structures that electrically connect the various regions of the SoC device 208 and/or electrically connect the various regions of the SoC device 208 with one or more external devices and/or external packaging. The interconnect structures 310a and metallization layers 312a may be referred to as a BEOL metallization stack, and may include a conductive material, such as gold, copper, silver, cobalt, tungsten, a metal alloy, or a combination thereof, among other examples.

In some implementations, portions of transistor circuitry may be included in the dielectric region 308b. For example, one or more source/drain regions 314b (e.g., a doped semiconductor material such as silicon (Si) or silicon germanium (SiGe)) may be included in the dielectric region 308b.

The SoC device 208 may further include a layer of a semiconductor material 304b. The layer of the semiconductor material 304b may include a semiconductor material such as silicon, a III-V compound such as gallium arsenide (GaAs), a silicon on insulator (SOI) layer, or another type of layer of a semiconductor material that is capable of generating a charge from photons of incident light.

Photodiodes 212 for visible light (VIS photodiodes) may be included within the layer of the semiconductor material 304b. The photodiodes 212 may include a plurality of types of ions to form a p-n junction or a p-i-n junction (e.g., a junction between a p-type portion, an intrinsic (or undoped) type portion, and an n-type portion). For example, the layer of the semiconductor material 304b may be doped with an n-type dopant to form a first portion (e.g., an n-type portion) of a photodiode 212 and a p-type dopant to form a second portion (e.g., a p-type portion) of the photodiode 212.

In some implementations, the layer of the semiconductor material 304b may further include portions of transistor circuitry. For example, the layer of the semiconductor material 304b may include a gate structure 306b. The gate structure 306b, which may be between the source/drain regions 314b, may include a conductive material such as a polysilicon material, among other examples. In some implementations, the transistor formed by the source/drain regions 314b and the gate structure 306b may be associated with the photodiode 212.

Further, and in some implementations of the SoC device 208, a shallow trench isolation (STI) region 318 may be the above the dielectric region 308b. The STI region 318 may electrically isolate the photodiodes 212 from other regions of the SoC device 208.

As shown in FIG. 3, an oxide layer 320 may be located above the layer of the semiconductor material 304b. The oxide layer 320 may function as a passivation layer between the layer of the semiconductor material 304b and the upper layers of the pixel sensors 204. In some implementations, the oxide layer 320 includes an oxide material such as a silicon oxide (SiOₓ). In some implementations, a silicon nitride (SiNₓ), a silicon carbide (SiCₓ), or a mixture thereof, such as a silicon carbon nitride (SiCN), a silicon oxynitride (SiON), or another dielectric material is used in place of the oxide layer 320 as a passivation layer.

The oxide layer 320 may fill deep trench isolation (DTI) structures 322 included in the layer of the semiconductor material 304b. In particular, DTI structures 322 may be formed between each of the photodiodes 212. The DTI structures 322 may include trenches (e.g., deep trenches) that extend downward into the layer of the semiconductor material 304b between the photodiodes 212. The DTI structures 322 may provide optical isolation between the photodiodes 212 to reduce the amount of optical crosstalk between adjacent photodiodes.

One or more high absorption (HA) regions 324 may be located above one or more photodiodes 212. Each HA region 324 may be defined by a shallow trench. A plurality of adjacent HA regions 324 may form a periodic or zig-zag structure in the layer of the semiconductor material 304b and/or the photodiodes 212. The one or more HA regions 324 may be formed in a same side of the layer of the semiconductor material 304b as the DTI structures 322.

The HA region 324 may increase the absorption of incident light for a photodiode 212 (thereby increasing the quantum efficiency of the photodiode 212) by modifying or changing the orientation of the refractive interface between the photodiodes and the layer of the semiconductor material 304b. The angled walls of the HA region 324 changes the orientation of the interface between the photodiodes 212 and the layer of the semiconductor material 304b by causing the interface to be diagonal relative to the orientation of a top surface of the layer of the semiconductor material 304b. This change in orientation may result in a smaller angle of refraction relative to a flat surface of the top surface of the layer of the semiconductor material 304b for the same angle of incidence of incident light. As a result, the HA region 324 is capable of directing wider angles of incident light toward the center of the photodiodes 212 than if no HA region 324 were included in the optoelectronic device 300.

In some implementations, a top surface of the layer of the semiconductor material 304b , the surfaces of the DTI structures 322, and the surfaces of the HA region 324 may be coated with an antireflective coating (ARC) layer to decrease reflection of incident light away from the photodiodes 212 to increase transmission of incident light into the layer of the semiconductor material 304b and the photodiodes 212.

As further shown in FIG. 3, one or more passivation layers may be formed above and/or on the oxide layer 320. For example, a backside illumination (BSI) oxide layer 326 may be located above and/or on portions of the oxide layer 320. As another example, a buffer oxide layer 328 may be located above and/or on the BSI oxide layer 326. In some implementations, the BSI oxide layer 326 and/or the buffer oxide layer 328 include an oxide material such as a silicon oxide (SiOₓ). In some implementations, a silicon nitride (SiNₓ), a silicon carbide (SiCₓ), or a mixture thereof, such as a silicon carbon nitride (SiCN), a silicon oxynitride (SiON), or another dielectric material is used in place of the BSI oxide layer 326 and/or the buffer oxide layer 328 as a passivation layer.

A bonding pad 330 may be located above the STI region 318, and/or above and/or on the buffer oxide layer 328. The bonding pad 330 may extend through the buffer oxide layer 328, through the STI region 318, and to the dielectric region 308b, and may contact one or more metallization layers 312b in the dielectric region 308b. The bonding pad 330 may include a conductive material, such as gold, silver, aluminum, copper, aluminum-copper, titanium, tantalum, titanium nitride, tantalum nitride, tungsten, a metal alloy, other metals, or a combination thereof. The bonding pad 330 may provide electrical connections between the metallization layers 312b of the optoelectronic device 300 and external devices and/or external packaging.

The filter layer 210 (e.g., corresponding to portions of a color filter array or a near infrared filter array) is included above and/or on the buffer oxide layer 328 for one or more pixel sensors 204. The filter layer 210 may include one or more visible light color filter regions configured to filter particular wavelengths or wavelength ranges of visible light (e.g., that permit particular wavelengths or wavelength ranges of visible light to pass through the filter layer 210), one or more near infrared (NIR) filter regions (e.g., NIR bandpass filter regions) configured to permit wavelengths associated with NIR light to pass through the filter layer 210 and to block other wavelengths of light, one or more NIR cut filter regions configured to block NIR light from passing through the filter layer 210, and/or other types of filter regions.

In some implementations, one or more pixel sensors 204 are each configured with a filter region of the filter layer 210. In some implementations, a micro-lens layer 332 is included above and/or on the filter layer 210. The micro-lens layer 332 may include a plurality of micro-lenses. In particular, the micro-lens layer 332 may include a respective micro-lens for pixel sensors in a pixel sensor array (e.g., each of the pixel sensors 204 included in the pixel sensor array 202).

As further shown in FIG. 3, the multi-layer structure including the layer of the quantum dot material 214, the layer of the conductive material 216, and the layer of conductive material 218, is between the ASIC device 206 and the SoC device 208. The photodiodes 220 (e.g., photodiodes including portions of the layer of the quantum dot material 214, portions the layer of the conductive material 216, and portions of the layer of the conductive material 218) are below NIR filters of the filter layer 210.

The number and arrangement of components, structures, and/or layers shown in the optoelectronic device 300 of FIG. 3 are provided as an example. In practice, the optoelectronic device 300 may include additional components, structures, and/or layers; fewer components, structures, and/or layers; different components, structures, and/or layers; and/or differently arranged components, structures, and/or layers than those shown in FIG. 3.

As described in connection with FIG. 3, a device (e.g., the optoelectronic device 200) includes a first photodiode (e.g., the photodiode 212) including a layer of a semiconductor material (e.g., the layer of the semiconductor material 304b) and a p-type dopant or an n-type dopant within the layer of the semiconductor material. The device includes a second photodiode (e.g., the photodiode 220) including a layer of a quantum dot material (e.g., the layer of the quantum dot material 214), a layer of a first conductive material (e.g., the layer of the conductive material 216) above the layer of the quantum dot material and in contact with the layer of the quantum dot material, and a layer of a second conductive material (e.g., the layer of the conductive material 218) below the layer of the quantum dot material and in contact with the layer of the quantum dot material.

The performance of the optoelectronic device 300 (e.g., a CIS device) including the photodiode 220 is improved relative to another optoelectronic device not including the photodiode. Improving the performance of the optoelectronic device 300 increases a manufacturing yield of the optoelectronic device 300 to a particular performance threshold. In addition to increasing the manufacturing yield, the combined NIR/SWIR and VIS light capabilities of the optoelectronic device 300 obviates the need for a separate and discrete optoelectronic device (e.g., a VIS light optoelectronic device) in an image detection system for a low-lighting environment. In this way, an amount of resources required to support a market that consumes a volume of the image detection system having NIR/SWIR and VIS light detection capabilities (e.g. semiconductor manufacturing tools, labor, raw materials, and/or computing resources) is reduced.

As indicated above, FIG. 3 is provided as an example. Other examples may differ from what is described with regard to FIG. 3.

FIGS. 4A-4O are diagrams of an example implementation 400 for forming the optoelectronic device of FIG. 3. As part of the implementation 400, one or more of the semiconductor processing tools 102-116 and/or the wafer/die transport tool 118 that are described in connection with FIG. 1 may perform a series of operations to form the optoelectronic device 300.

As shown in FIG. 4A, the layer of the semiconductor material 304a is formed over and/or on the substrate 302. The deposition tool 102 may deposit the layer of the semiconductor material 304a in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the semiconductor material after the deposition tool 102 deposits the layer of the semiconductor material 304a.

As shown in FIG. 4B, the gate structure 306a may be formed in the layer of the

semiconductor material 304a. As an example, the deposition tool 102, the exposure tool 104, the developer tool 106, the etch tool 108, and/or the ion implantation tool 114 may perform a combination of deposition, photolithography, etching, and/or implant operations to form the gate structure 306a.

As shown in FIG. 4C, the dielectric region 308a is formed on and/or over the layer of the semiconductor material 304a. As part of forming the dielectric region 308a, and as an example, the deposition tool 102 may deposit one or more dielectric layers of the dielectric region 308a using a CVD operation, a PVD operation, an ALD operation, another deposition operation described above in connection with FIG. 1, and/or another suitable deposition operation. In some implementations, the planarization tool 110 planarizes the one or more of the dielectric layers after the deposition tool 102 deposits the dielectric layers.

Additionally, or alternatively and as part of forming the dielectric region 308a, the deposition tool 102, the exposure tool 104, the developer tool 106, the etch tool 108, and/or the ion implantation tool 114 may perform a combination of deposition, photolithography, etching, and/or implant operations to form the source/drain regions 314a within the dielectric region 308a.

Additionally, or alternatively and as part of forming the dielectric region 308a, the deposition tool 102, the exposure tool 104, the developer tool 106, and/or the etch tool 108 may perform a combination of deposition, photolithography, and/or etching operations to form one or more metallization layers 312a. To form the one or more of the metallization layers 312a, the deposition tool 102 and/or the plating tool 112 may deposit one or more of the metallization layers 312a in a CVD operation, a PVD operation, an ALD operation, an electroplating operation, another deposition operation described above in connection with FIG. 1, and/or another suitable deposition operation. In some implementations, the planarization tool 110 planarizes one or more of the metallization layers 312a after deposition.

Additionally, or alternatively as part of forming the dielectric region 308a, the deposition tool 102, the exposure tool 104, the developer tool 106, and/or the etch tool 108 may perform a combination of deposition, photolithography, and/or etching operations to form the interconnect structures 310a.

Turning to FIG. 4D, the layer of the conductive material 218 is formed on and/or over the dielectric region 308a. The deposition tool 102 and/or the plating tool 112 may deposit the layer of the conductive material 218 in a CVD operation, a PVD operation, an ALD operation, an electroplating operation, another deposition operation described above in connection with FIG. 1, and/or another suitable deposition operation. In some implementations, a seed layer is first deposited, and the layer of the conductive material 218 is deposited on the seed layer. In some implementations, the planarization tool 110 planarizes the layer of the conductive material 218 after the deposition tool 102 and/or the plating tool 112 deposits the layer of the conductive material 218.

As shown in FIG. 4E, the layer of the quantum dot material 214 is formed on and/or over the layer of the conductive material 218. The deposition tool 102 may deposit the layer of the quantum dot material 214 in a spin coating operation, an ALD operation, another type of deposition operation described in connection with FIG. 1, and/or another suitable deposition operation. In some implementations, the planarization tool 110 planarizes the layer of the quantum dot material 214 after the deposition tool 102 deposits the layer of the quantum dot material 214.

In some implementations, the deposition tool 102 may deposit the layer of the quantum dot material 214 such that a thickness D1 of the layer of the quantum dot material 214 is included in a range of approximately 180 nanometers to approximately 220 nanometers. If the thickness D1 is less than approximately 180 nanometers, a resistivity property of the layer of the quantum dot material 214 may not satisfy a threshold. If the thickness is greater than approximately 220 nanometers, a transmissivity characteristic of the layer of the quantum dot material 214 not satisfy a threshold. However, other values and ranges for the thickness D1 are within the scope of the present disclosure.

As shown in FIG. 4F, the layer of the conductive material 216 is formed on and/or over layer of the quantum dot material 214. The deposition tool 102 and/or the plating tool 112 may deposit the layer of the conductive material 216 in a CVD operation, a PVD operation, an ALD operation, an electroplating operation, another deposition operation described above in connection with FIG. 1, and/or another suitable deposition operation. In some implementations, a seed layer is first deposited, and the layer of the conductive material 216 is deposited on the seed layer. In some implementations, the planarization tool 110 planarizes the layer of the conductive material 216 after the deposition tool 102 and/or the plating tool 112 deposits the layer of the conductive material 216.

Turning to FIG. 4G, a portion of the SoC device 208 (e.g., a partially formed portion of the SoC device 208 including the dielectric region 308b, the layer of the semiconductor material 304b, and the photodiodes 212 and that is formed through a separate series of operations) may be joined with the layer of the conductive material 216. As an example, joining the portion of the SoC device 208 may include the bonding tool 116 performing a eutectic bonding operation that joins the dielectric region 308a of the SoC device 208 and the layer of the conductive material 216. Joining the dielectric region 308a and the layer of the conductive material 216 may provide electrical connectivity between one or more of the metallization layers 312b of the SoC device 208 to form the photodiode 220 from the multi-layer stack that includes the layer of conductive material 218, the layer of the quantum dot material 214, and the layer of the conductive material 216.

As shown in FIG. 4H, and as part of implementation 400, the etch tool 108 may form cavities 402 (e.g., cavities for the DTI structures 322) and cavities 404 (e.g., cavities for the HA regions 324). In some implementations, a pattern in a photoresist layer is used to etch the layer of the semiconductor material 304b to form the cavities 402 and 404. In these implementations, the deposition tool 102 forms the photoresist layer on the layer of the semiconductor material 304b. The exposure tool 104 exposes the photoresist layer to a radiation source to pattern the photoresist layer. The developer tool 106 develops and removes portions of the photoresist layer to expose the pattern. The etch tool 108 etches the layer of the semiconductor material 304b based on the pattern to form the cavities 402 and 404 in the layer of the semiconductor material 304b. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the layer of the semiconductor material 304b based on a pattern.

As shown in FIG. 4I, the oxide layer 320 is formed over and/or on the layer of the semiconductor material 304b. The deposition tool 102 may deposit the oxide layer 320 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the oxide layer 320 after the deposition tool 102 deposits the oxide layer 320. As part of forming the oxide layer 320, the cavities 402 and 404 may be filled with oxide to form the DTI structures 322 and the HA regions 324. In some implementations, the deposition tool 102 deposits an anti-reflective (ARC) layer prior to depositing the oxide layer 320.

As shown in FIG. 4J, the BSI oxide layer 326 is formed over and/or on the oxide layer 320. The deposition tool 102 may deposit the BSI oxide layer 326 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the BSI oxide layer 326 after the deposition tool 102 deposits the BSI oxide layer 326.

Turning to FIG. 4K, and as part of the implementation 400, a cavity 406 is formed through the BSI oxide layer 326, the oxide layer 320, and the layer of the semiconductor material 304b to the STI region 318. In some implementations, a pattern in a photoresist layer is used to etch the BSI oxide layer 326, the oxide layer 320, and the layer of the semiconductor material 304b to form the cavity 406. In these implementations, the deposition tool 102 forms the photoresist layer on the layer of the semiconductor material 304b. The exposure tool 104 exposes the photoresist layer to a radiation source to pattern the photoresist layer. The developer tool 106 develops and removes portions of the photoresist layer to expose the pattern. The etch tool 108 etches the cavity 406 based on the pattern to form the cavity 406 in the BSI oxide layer 326, the oxide layer 320, and the layer of the semiconductor material 304b. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the BSI oxide layer 326, the oxide layer 320, and the layer of the semiconductor material 304b based on a pattern.

As shown in FIG. 4L, the buffer oxide layer 328 is formed over and/or on the BSI oxide layer 326. The deposition tool 102 may deposit the buffer oxide layer 328 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the buffer oxide layer 328 after the deposition tool 102 deposits the buffer oxide layer 328.

As shown FIG. 4M, cavities 408 are formed through buffer oxide layer 328, through the STI region 318, and into the dielectric region 308b. In some implementations, a pattern in a photoresist layer is used to etch the buffer oxide layer 328, the STI region 318, and the dielectric region 308b to form cavities 408. In these implementations, the deposition tool 102 forms the photoresist layer on the buffer oxide layer 328. The exposure tool 104 exposes the photoresist layer to a radiation source to pattern the photoresist layer. The developer tool 106 develops and removes portions of the photoresist layer to expose the pattern. The etch tool 108 etches the buffer oxide layer 328, the STI region 318, and the dielectric region 308b based on the pattern to form the cavities 408 through buffer oxide layer 328, through the STI region 318, and into the dielectric region 308b. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the buffer oxide layer 328, the STI region 318, and the dielectric region 308b based on a pattern.

As part of implementation 400 and as shown in FIG. 4N, the bonding pad 330 is formed in the cavities 408. As an example, the deposition tool 102, the exposure tool 104, the developer tool 106, and/or the etch tool 108 may perform a combination of deposition, photolithography, and/or etching operations to form the bonding pad 330.

Turning to FIG. 4O, the filter layer 210 and the micro-lens layer 332 are formed over and/or on the buffer oxide layer 328. As an example, the deposition tool 102, the exposure tool 104, the developer tool 106, and/or the etch tool 108 may perform a combination of deposition, photolithography, and/or etching operations to form the filter layer 210 and the micro-lens layer 332.

As indicated above, FIGS. 4A-4O are provided as an example. Other examples may differ from what is described with regard to FIGS. 4A-4O.

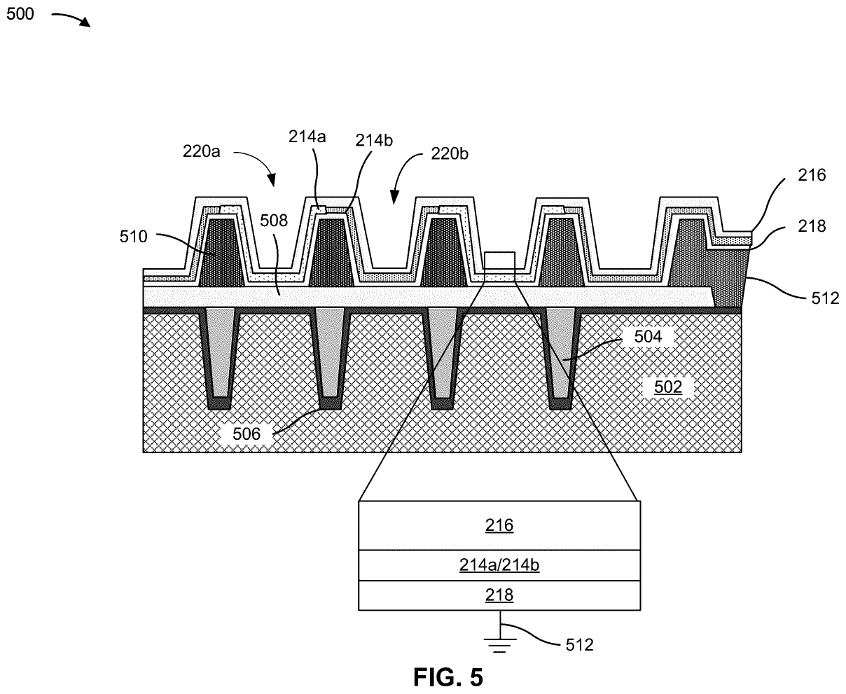

FIG. 5 is a diagram of an example optoelectronic device 500 described herein. The optoelectronic device 500 may be an optoelectronic device that is configured to detect electromagnetic waves having wavelengths that correspond to NIR and/or SWIR light waves. The optoelectronic device 500 may be included in an image sensor such as a complementary metal-oxide semiconductor (CMOS) image sensor, a backside illumination (BSI) CMOS image sensor, or another type of image sensor. The optoelectronic device 500 includes a photodiode 220a to detect NIR light waves and an adjacent photodiode 220b to detect SWIR light waves.

As shown in FIG. 5, the optoelectronic device 500 includes a substrate layer 502. The substrate layer 502 be formed of silicon (Si) (e.g., a silicon substrate), a material including silicon, a III-V compound semiconductor material such as gallium arsenide (GaAs), a silicon on insulator (SOI), or another type of semiconductor material.

The optoelectronic device 500 further includes DTI structures 504 that penetrate into the substrate layer 502. The DTI structures 504, which may reduce cross talk between the photodiodes 220a and 220b, may include an oxide material, among other examples. The optoelectronic device further includes an antireflective coating (ARC) layer 506 to decrease reflection of incident light within the optoelectronic device 500. The ARC layer 506 may include a nitrogen-containing material, among other examples.

An oxide layer 508 may be on and/or above the ARC layer 506. The oxide layer 508 may function as a dielectric buffer layer between underlying structures of the optoelectronic device 500 and the photodiodes 220a/220b. The oxide layer 508 may include an oxide material such as a silicon oxide (SiOₓ) (e.g., silicon dioxide (SiO₂)), a silicon nitride (SiNₓ), a silicon carbide (SiCₓ), a titanium nitride (TiNₓ), a tantalum nitride (TaNₓ), a hafnium oxide (HfOₓ), a tantalum oxide (TaOₓ), or an aluminum oxide (AlOₓ), and/or another dielectric material that is capable of providing optical isolation within the optoelectronic device.

An array of pillar structures 510 may be on and/or over the oxide layer 508. The array of pillar structures 510 may include a metal material such as tungsten (W), copper (Cu), aluminum (Al), cobalt (Co), nickel (Ni), titanium (Ti), tantalum (Ta), another conductive material, and/or an alloy including one or more of the foregoing. Additionally, or alternatively, the array of pillar structures 510 may include a reflective material that is not conductive. As further shown in FIG. 5, the optoelectronic device 500 includes a grounding node 512.

In FIG. 5, the photodiodes 220a and 220b are on and/or over contours of the array of pillar structures 510. The array of pillar structures 510 may reflect incident light within the photodiodes 220a and/or 220b to increase an intensity of light absorbed within the photodiodes 220a and/or 220b.

The photodiode 220a includes the layer of the quantum dot material 214a and the photodiode 220b includes the layer of the quantum dot material 214b. The layers of the quantum dot material 214a and 214b may include quantum dots to form p-n junctions between the layer of the conductive material 216 and the layer of the conductive material 218. As shown in FIG. 5, the layer of the conductive material 218 is below the layers of quantum dot materials 214a and 214b and the layer of the conductive material 216 is above the layers of the quantum dot materials 214a and 214b. The layer of the conductive material 218 connects to the grounding node 512.

To detect NIR light waves (e.g., electromagnetic waves having a wavelength that is included in a range of approximately 800 nanometers to approximately 900 nanometers), and as an example, the layer of the quantum dot material 214a (e.g., the photodiode 220a) may include a mixture of lead sulfide (PbS) quantum dots. The mixture of PbS quantum dots in the layer of the quantum dot material 214a may have diameters that are included in a range of approximately 4nanometers to approximately 6 nanometers. However, other materials and diameters for the mixture of quantum dots in the layer of the quantum dot material 214a are within the scope of the present disclosure.

To detect SWIR light waves (e.g., electromagnetic waves having a wavelength that is included in a range of approximately 1000 nanometers to approximately 2500 nanometers), and as an example, the layer of the quantum dot material 214b (e.g., the photodiode 220b) may include a mixture of PbS quantum dots. In contrast to mixture of the PbS quantum dots in the layer of the quantum dot material 214a, and due to the longer wavelengths of the SWIR light waves, the mixture of PbS quantum dots in the layer of the quantum dot material 214b may have diameters that are included in a range of approximately 5 nanometers to approximately 12 nanometers. However, other materials and diameters for the mixture of quantum dots in the layer of the quantum dot material 214b are within the scope of the present disclosure.

As shown in FIG. 5, and in some implementations, a device (e.g., the optoelectronic device 300) includes an array of pillar structures (e.g., the array of pillar structures 510). The device includes a photodiode (e.g., the photodiode 220a and/or 220b) over contours of the array of pillar structures. The photodiode includes a layer of a first conductive material (e.g., the layer of conductive material 218) that conforms to the contours of the array of pillar structures, a layer of a quantum dot material (e.g. the layer of the quantum dot material 214a and/or the layer of the quantum dot material 214b) on the layer the first conductive material, and a layer of a second conductive material on the quantum dot material (e.g., the layer of the conductive material 216).

As indicated above, FIG. 5 is provided as an example. Other examples may differ from what is described with regard to FIG. 5.

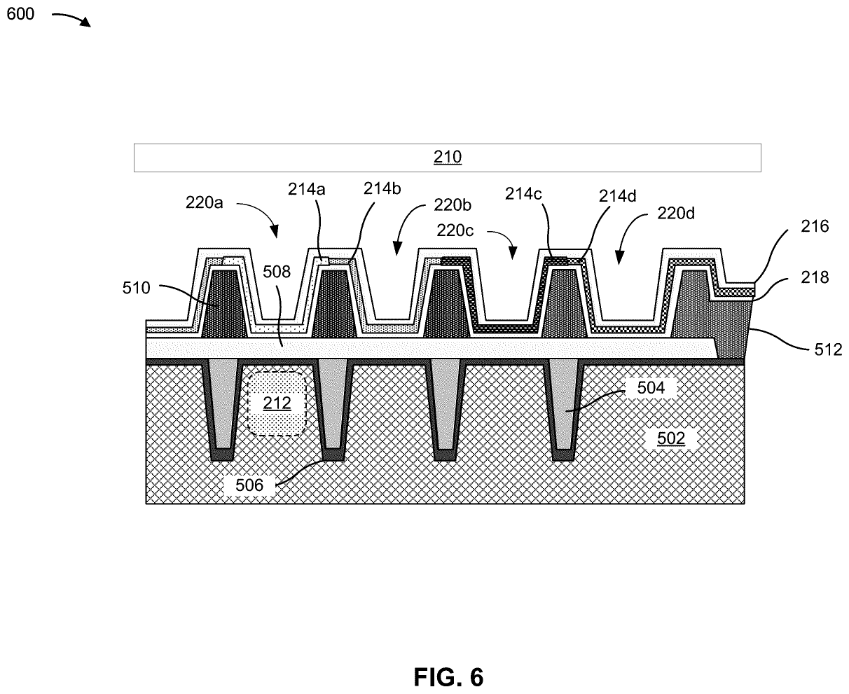

FIG. 6 is a diagram of an example optoelectronic device 600 described herein. The optoelectronic device 600 may be an optoelectronic device that is configured to detect electromagnetic waves having wavelengths that correspond to NIR light waves, SWIR light waves, and/or visible (VIS) light waves. The optoelectronic device 600 may be included in an image sensor such as a complementary metal-oxide semiconductor (CMOS) image sensor, a backside illumination (BSI) CMOS image sensor, or another type of image sensor.

The optoelectronic device 600 includes the photodiode 220a to detect NIR light waves (e.g., the photodiode 220a including the layer of the quantum dot material 214a). The optoelectronic device further includes the photodiode 220b to detect SWIR light waves (e.g., the photodiode 220b including the layer of the quantum dot material 214b).

As shown in FIG. 6, the optoelectronic device includes the photodiode 220c to detect blue VIS light waves. To detect blue VIS light waves (e.g., electromagnetic waves having a wavelength that is included in a range of approximately 450 nanometers to approximately 490 nanometers), and as an example, the layer of the quantum dot material 214c (e.g., the photodiode 220c) may include a mixture of lead sulfide (PbS) quantum dots. The mixture of PbS quantum dots in the layer of the quantum dot material 214c may have diameters that are included in a range of approximately 3 nanometers to approximately 4 nanometers. However, other materials and diameters for the mixture of quantum dots in the layer of the quantum dot material 214c are within the scope of the present disclosure.

As shown in FIG. 6, the optoelectronic device includes the photodiode 220d to detect green VIS light waves. To detect green VIS light waves (e.g., electromagnetic waves having a wavelength that is included in a range of approximately 495 nanometers to approximately 570 nanometers), and as an example, the layer of the quantum dot material 214d (e.g., the photodiode 220d) may include a mixture of lead sulfide (PbS) quantum dots. The mixture of PbS quantum dots in the layer of the quantum dot material 214d may have diameters that are included in a range of approximately 4 nanometers to approximately 5 nanometers. However, other materials and diameters for the mixture of quantum dots in the layer of the quantum dot material 214d are within the scope of the present disclosure.

Further, the optoelectronic device includes the photodiode 212 to detect red VIS light waves corresponding to red VIS light waves (e.g., electromagnetic waves having wavelengths that are included in a range of approximately 620 nanometers to approximately 750 nanometers). As shown in FIG. 6, the photodiode 212 (e.g., an organic photodiode formed in the substrate layer 502 through a doping operation) is below the photodiode 220a. The photodiode 212 may be located below the photodiode 220a to conserve space in the optoelectronic device 600.

As shown in FIG. 6, the filter layer 210 is located above the photodiodes 220a-220d and the photodiode 212. The filter layer 210 may include a region above the photodiodes 212 and 220a that is transmissive to NIR light waves and red VIS light waves. Additionally, or alternatively, the filter layer 210 may include a region above the photodiode 220b that is transmissive to SWIR light waves. Additionally, or alternatively, the filter layer 210 may include a region above the photodiode 220c that is transmissive to blue VIS light waves. Additionally, or alternatively, the filter layer 210 may include a region above the photodiode 220d that is transmissive to green VIS light waves.

The performance of the optoelectronic device 600 (e.g., a CIS device) including the photodiodes 220a and 220b is improved relative to another optoelectronic device not including the photodiodes 220a and 220b. Improving the performance of the optoelectronic device 600 increases a manufacturing yield of the optoelectronic device 600 to a particular performance threshold. In addition to increasing the manufacturing yield, the combined NIR/SWIR and VIS light capabilities of the optoelectronic device 600 obviates the need for a separate and discrete optoelectronic device (e.g., a VIS light optoelectronic device) in an image detection system for a low-lighting environment. In this way, an amount of resources required to support a market that consumes a volume of the image detection system having NIR/SWIR and VIS light detection capabilities (e.g. semiconductor manufacturing tools, labor, raw materials, and/or computing resources) is reduced.

The number and arrangement of devices shown in FIG. 6 are provided as one or more examples. In practice, there may be additional photodiodes, fewer photodiodes, different photodiodes, or differently arranged photodiodes than those shown in FIG. 6.

FIGS. 7A-7I are diagrams of an example implementation 700 described herein. As part of the implementation 700, one or more of the semiconductor processing tools 102-116 and/or the wafer/die transport tool 118 that are described in connection with FIG. 1 may perform a series of operations to form the optoelectronic device 500 including the photodiodes 220a and 220b.

As shown in FIG. 7A, the example process for forming the optoelectronic device may be performed in connection with the substrate layer 502. In FIG. 7A, the substrate layer 502 may include a semiconductor die substrate, a semiconductor wafer, a stacked semiconductor wafer, or another type of substrate in which the optoelectronic device 500 may be formed. For example, the substrate layer 502 may be formed of silicon (Si) (e.g., a silicon substrate), a material including silicon, a III-V compound semiconductor material such as gallium arsenide (GaAs), a silicon on insulator (SOI), or another type of semiconductor material. As further shown in FIG. 7A, the DTI structure 504 may be included in the substrate layer 502. The DTI structures 504 may be coated or lined with the ARC layer 506.

In FIG. 7A, the oxide layer 508 is formed on and/or over the substrate layer 502. To form the oxide layer 508, the deposition tool 102 may deposit the oxide layer 508 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the oxide layer 508 after the deposition tool 102 deposits the oxide layer 508.

As further shown in FIG. 7A, the array of pillar structures 510 may be formed over the oxide layer 508. For example, the deposition tool 102 may deposit layer of a metal material over and/or on the frontside surface of the substrate layer 502 (e.g., over the oxide layer 320). In some implementations, the deposition tool 102 may deposit the metal material using a CVD operation, a PVD operation, an ALD operation, a plating operation, another type of deposition operation described in connection with FIG. 1, and/or another suitable deposition operation

Accordingly, the deposition tool 102 may form a photoresist layer over and/or on the layer of the metal material, the exposure tool 104 may expose the photoresist layer to a radiation source to form a pattern on the photoresist layer, and the developer tool 106 may develop and remove portions of the photoresist layer to expose the pattern. Accordingly, the etch tool 108 may etch portions of the layer of the metal material to form the array of pillar structures 510. For example, the etch tool 108 may use a wet etch technique, a dry etch technique, a plasma-enhanced etch technique, and/or another type of etch technique to etch the portion of layer of the metal material to form the array of pillar structures 510. A photoresist removal tool may remove the remaining portions of the photoresist layer (e.g., using a chemical stripper, a plasma asher, and/or another technique) after the etch tool 108 etches the metal layer to form the metal structures. In addition to array of pillar structures 510, the grounding node 512 may be formed. For example, the grounding node 512 may be formed concurrently with the metal structures.

As shown in FIG. 7B, the layer of conductive material 218 (e.g., a bottom electrode layer) is formed. For example, the deposition tool 102 may form the layer of conductive material 218 over and/or on the frontside surface of the substrate layer 502 and/or along contours of the array of pillar structures 510. In some implementations, the deposition tool 102 may deposit the layer of the conductive material 218 using a CVD operation, a PVD operation, an ALD operation, a plating operation, another type of deposition operation described in connection with FIG. 1, and/or another suitable deposition operation.

As shown in FIG. 7C, the layer of the quantum dot material 214a is formed on and/or over the layer of the conductive material 218. For example, deposition tool 102 may deposit the layer of the quantum dot material 214a using a spin coating operation, an ALD operation, another type of deposition operation described in connection with FIG. 1, and/or another suitable deposition operation.

As shown in FIG. 7D, one or more masking layers (e.g., a photoresist layer 702 in example implementation 700) may be formed over the layer of conductive material 218. For example, the deposition tool 102 may form the photoresist layer 702 over and/or on the frontside surface of the substrate layer 502 (e.g., over the layer of the conductive material 218). In some implementations, the deposition tool 102 may deposit the photoresist layer 702 using a spin-coating another type of deposition operation described in connection with FIG. 1, and/or another suitable deposition operation. In some implementations, the photoresist layer 702 may be formed over the entire layer of the conductive material 218. Accordingly, the exposure tool 104 may expose the photoresist layer 702 to a radiation source to form a pattern on the photoresist layer 702, and the developer tool 106 may develop and remove portions of the photoresist layer 702 to expose the pattern. As shown in FIG. 7D, the pattern may be such that the photoresist layer 702 is over portions of the layer of the quantum dot material 214a.

As shown in FIG. 7E, portions of the layer of the quantum dot material 214a are removed. Accordingly, the etch tool 108 may etch a portion of layer of the quantum dot material 214a not protected by the pattern of the photoresist layer 702. For example, the etch tool 108 may use a wet etch technique, a dry etch technique, a plasma-enhanced etch technique, and/or another type of etch technique to etch the portions of the layer of the quantum dot material 214a. A photoresist removal tool may remove the remaining portions of the photoresist layer 702 (e.g., using a chemical stripper, a plasma asher, and/or another technique) after the etch tool 108 etches the portions of the layer of the quantum dot material 214a.

As shown in FIG. 7F, the layer of the quantum dot material 214b is formed over the array of pillar structures 510. For example, the deposition tool 102 may form the layer of the quantum dot material 214b over and/or along contours of the layer of the conductive material 218. Additionally, or alternatively, the deposition tool 102 may form the layer of the quantum dot material 214b over and/or along contours of the layer of the conductive material 218. For example, deposition tool 102 may deposit the layer of the quantum dot material 214b using a spin coating operation, an ALD operation, another type of deposition operation described in connection with FIG. 1, and/or another suitable deposition operation.

As shown in FIG. 7G, one or more masking layers (e.g., a photoresist layer 704 in example implementation 700) may be formed over the layer of the quantum dot material 214b. For example, the deposition tool 102 may form the photoresist layer 704 over and/or on the layer of the quantum dot material 214b. In some implementations, the deposition tool 102 deposits the photoresist layer 704 using a spin-coating operation, another type of deposition operation described in connection with FIG. 1, and/or another suitable deposition operation. In some implementations, the photoresist layer 704 may be formed over the entire layer of the quantum dot material 214b. Accordingly, the exposure tool 104 may expose the photoresist layer 704 to a radiation source to form a pattern on the photoresist layer 704, and the developer tool 106 may develop and remove portions of the photoresist layer 704 to expose the pattern. As shown in FIG. 7G, the pattern may be such that the photoresist layer 704 is over portions of the layer of the quantum dot material 214b.

As shown in FIG. 7H, portions of the layer of the quantum dot material 214b over the layer of the conductive material 218 are etched. Accordingly, the etch tool 108 may etch a portion of layer of the quantum dot material 214b not protected by the pattern of the photoresist layer 704. For example, the etch tool 108 may use a wet etch technique, a dry etch technique, a plasma-enhanced etch technique, and/or another type of etch technique to etch the portions of the layer of the quantum dot material 214b. A photoresist removal tool may remove the remaining portions of the photoresist layer 704 (e.g., using a chemical stripper, a plasma asher, and/or another technique) after the etch tool 108 etches the portions of the layer of the quantum dot material 214a.

As shown in FIG. 7I, the layer of conductive material 216 (e.g., a top electrode layer) is formed. For example, the deposition tool 102 may form the layer of conductive material 216 over and/or on layer of the quantum dot material 214a and/or the layer of the quantum dot material 214b. In some implementations, the deposition tool 102 may deposit the layer of the conductive material 218 using a CVD operation, a PVD operation, an ALD operation, a plating operation, another type of deposition operation described in connection with FIG. 1, and/or another suitable deposition operation.

As indicated above, FIGS. 7A-7I are provided as an example. Other examples may differ from what is described with regard to FIGS. 7A-7I.

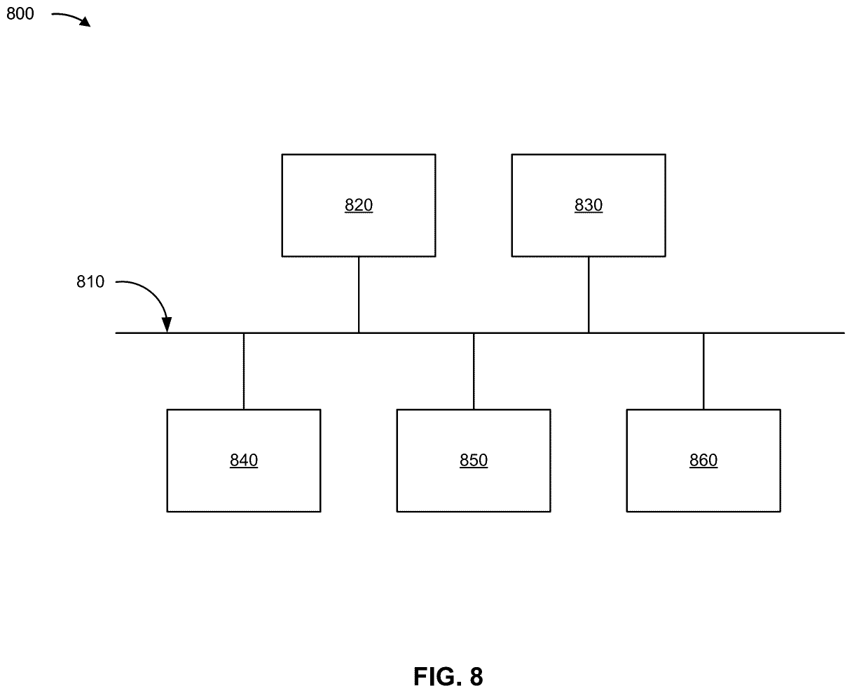

FIG. 8 is a diagram of example components of a device 800 described herein. In some implementations, one or more of the semiconductor processing tools 102-116 and/or the wafer/die transport tool 118 may include one or more devices 800. As shown in FIG. 8, the device 800 may include a bus 810, a processor 820, a memory 830, an input component 840, an output component 850, and/or a communication component 860.

The bus 810 may include one or more components that enable wired and/or wireless communication among the components of the device 800. The bus 810 may couple together two or more components of FIG. 8, such as via operative coupling, communicative coupling, electronic coupling, and/or electric coupling. For example, the bus 810 may include an electrical connection (e.g., a wire, a trace, and/or a lead) and/or a wireless bus. The processor 820 may include a central processing unit, a graphics processing unit, a microprocessor, a controller, a microcontroller, a digital signal processor, a field-programmable gate array, an application-specific integrated circuit, and/or another type of processing component. The processor 820 may be implemented in hardware, firmware, or a combination of hardware and software. In some implementations, the processor 820 may include one or more processors capable of being programmed to perform one or more operations or processes described elsewhere herein.

The memory 830 may include volatile and/or nonvolatile memory. For example, the memory 830 may include random access memory (RAM), read only memory (ROM), a hard disk drive, and/or another type of memory (e.g., a flash memory, a magnetic memory, and/or an optical memory). The memory 830 may include internal memory (e.g., RAM, ROM, or a hard disk drive) and/or removable memory (e.g., removable via a universal serial bus connection). The memory 830 may be a non-transitory computer-readable medium. The memory 830 may store information, one or more instructions, and/or software (e.g., one or more software applications) related to the operation of the device 800. In some implementations, the memory 830 may include one or more memories that are coupled (e.g., communicatively coupled) to one or more processors (e.g., processor 820), such as via the bus 810. Communicative coupling between a processor 820 and a memory 830 may enable the processor 820 to read and/or process information stored in the memory 830 and/or to store information in the memory 830.

The input component 840 may enable the device 800 to receive input, such as user input and/or sensed input. For example, the input component 840 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 850 may enable the device 800 to provide output, such as via a display, a speaker, and/or a light-emitting diode. The communication component 860 may enable the device 800 to communicate with other devices via a wired connection and/or a wireless connection. For example, the communication component 860 may include a receiver, a transmitter, a transceiver, a modem, a network interface card, and/or an antenna.

The device 800 may perform one or more operations or processes described herein. For example, a non-transitory computer-readable medium (e.g., memory 830) may store a set of instructions (e.g., one or more instructions or code) for execution by the processor 820. The processor 820 may execute the set of instructions to perform one or more operations or processes described herein. In some implementations, execution of the set of instructions, by one or more processors 820, causes the one or more processors 820 and/or the device 800 to perform one or more operations or processes described herein. In some implementations, hardwired circuitry may be used instead of or in combination with the instructions to perform one or more operations or processes described herein. Additionally, or alternatively, the processor 820 may be configured to perform one or more operations or processes described herein. Thus, implementations described herein are not limited to any specific combination of hardware circuitry and software.

The number and arrangement of components shown in FIG. 8 are provided as an example. The device 800 may include additional components, fewer components, different components, or differently arranged components than those shown in FIG. 8. Additionally, or alternatively, a set of components (e.g., one or more components) of the device 800 may perform one or more functions described as being performed by another set of components of the device 800.

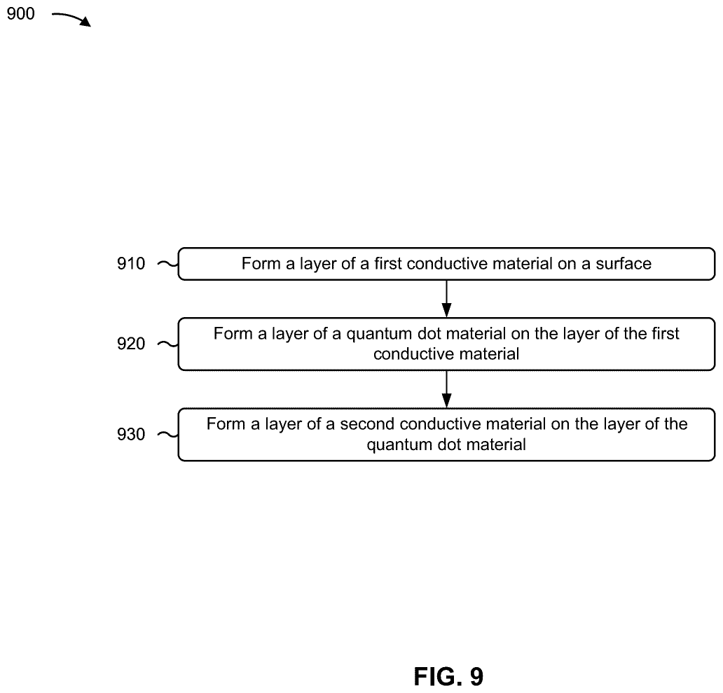

FIG. 9 is a flowchart of an example process 900 associated with forming an optoelectronic device with a photodiode that includes a quantum dot material. In some implementations, one or more process blocks of FIG. 9 are performed by one or more semiconductor processing tools (e.g., one or more of the semiconductor processing tools 102-116). Additionally, or alternatively, one or more process blocks of FIG. 9 may be performed by one or more components of device 800, such as processor 820, memory 830, input component 840, output component 850, and/or communication component 860.

As shown in FIG. 9, process 900 may include forming a layer of a first conductive material on a surface (block 910). For example, one or more of the semiconductor processing tools 102-116 may form a layer of a first conductive material (e.g., the layer of the conductive material 218) on a surface (e.g., on a surface of the dielectric region 308a or on a surface corresponding to contours of the array of pillar structures 510), as described herein.

As further shown in FIG. 9, process 900 may include forming a layer of a quantum dot material on the layer of the first conductive material (block 920). For example, one or more of the semiconductor processing tools 102-116 may form a layer of a quantum dot material (E.g., the layer of the quantum material 214, 214a, or 214b) on the layer of the first conductive material, as described herein.

As further shown in FIG. 9, process 900 may include forming a layer of a second conductive material on the layer of the quantum dot material (block 930). For example, one or more of the semiconductor processing tools 102-116 may form a layer of a second conductive material (e.g., the layer of the conductive material 216) on the layer of the quantum dot material, as described herein. In some implementations, the second conductive material is transmissive to near infrared light or to short-wave infrared light.

Process 900 may include additional implementations, such as any single implementation or any combination of implementations described below and/or in connection with one or more other processes described elsewhere herein.

In a first implementation, forming the layer of the quantum dot material includes forming the layer of the quantum dot material using an atomic layer deposition process, or forming the layer of the quantum dot material using a spin coating process.

In a second implementation, alone or in combination with the first implementation, forming the layer of the first conductive material on the surface includes forming the layer of the first conductive material along a contour of a metal pillar (e.g., of the array of metal pillars 510) that is above a deep trench isolation structure (e.g., the DTI structure 504) included in an optoelectronic device (e.g., the optoelectronic device 500).

In a third implementation, alone or in combination with one or more of the first and second implementations, forming the layer of the quantum dot material on the layer of the first conductive material includes forming a first layer of a first quantum dot material (e.g., the layer of the quantum dot material 214a) on the layer of the first conductive material and further including removing portions of the first layer of the first quantum dot material to expose portions of the layer of the first conductive material, and forming a second layer of a second quantum dot material (e.g., the layer of the quantum dot material 214b) on the portions of the layer of the first conductive material.

In a fourth implementation, alone or in combination with one or more of the first through third implementations, forming the layer of the first conductive material on the surface includes forming the layer of the first conductive material on a top surface of an application specific integrated circuit device (e.g., the ASIC 206).

In a fifth implementation, alone or in combination with one or more of the first through fourth implementations, process 900 includes joining the application specific integrated circuit device to a portion of another integrated circuit device (e.g., a portion of the SoC 208) using a eutectic bonding process, where the eutectic bonding process joins the layer of the second conductive material to a bottom surface of the portion of the other integrated circuit device.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

Some implementations described herein include a CIS device for an image detection system that is used in a low-light environment. The CIS device includes a photodiode for detecting NIR and/or SWIR light waves. The photodiode includes a layer of a quantum dot material and a transparent electrode over the layer of the quantum dot material. In addition to the photodiode having an improved QE relative to a silicon-based photodiode, the photodiode may be integrated within a color filter array structure to obviate the need for separate a separate visible light (VIS) CIS device in the image detection system.

In this way, a performance (e.g., an NIR/SWIR QE) of a CIS device including the photodiode is improved relative to another CIS device not including the photodiode. Improving the performance of the CIS device increases a manufacturing yield of the CIS device to a particular performance threshold. By increasing the manufacturing yield and obviating the need for a separate VIS device space and/or image detection system space, an amount of resources required to support a market that consumes a volume of the image detection system having NIR/SWIR and VIS light detection capabilities (e.g. semiconductor manufacturing tools, labor, raw materials, and/or computing resources) is reduced.

As described in greater detail above, some implementations described herein provide a device. The device includes a first photodiode including a layer of a semiconductor material and a p-type dopant or an n-type dopant within the layer of the semiconductor material. The device includes a second photodiode including a layer of a quantum dot material, a layer of a first conductive material above the layer of the quantum dot material and in contact with the layer of the quantum dot material, and a layer of a second conductive material below the layer of the quantum dot material and in contact with the layer of the quantum dot material.

As described in greater detail above, some implementations described herein provide a device. The device includes an array of metal pillar structures. The device includes a photodiode over contours of the array of metal pillar structures. The photodiode includes a layer of a first conductive material that conforms to the contours of the array of metal pillar structures, a layer of a quantum dot material on the layer the first conductive material, and a layer of a second conductive material on the quantum dot material.

As described in greater detail above, some implementations described herein provide a method. The method includes forming a layer of a first conductive material on a surface. The method includes forming a layer of a quantum dot material on the layer of the first conductive material. The method includes forming a layer of a second conductive material on the layer of the quantum dot material, where the second conductive material is transmissive to near infrared light or to short-wave infrared light.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first photodiode comprising:
a layer of a semiconductor material; and
a p-type dopant or an n-type dopant within the layer of the semiconductor material; and
a second photodiode comprising:
a layer of a quantum dot material;
a layer of a first conductive material above the layer of the quantum dot material and in contact with the layer of the quantum dot material; and
a layer of a second conductive material below the layer of the quantum dot material and in contact with the layer of the quantum dot material.

2. The device of claim 1, wherein the second photodiode is below the layer of the semiconductor material.

3. The device of claim 1, wherein the layer of the first conductive material comprises:
a conductive material that is transmissive to near infrared light waves.

4. The device of claim 1, wherein the layer of the first conductive material comprises:
a conductive material that is transmissive to short-wave infrared light waves.

5. The device of claim 1, wherein the layer of the first conductive material comprises:
a tin oxide material including an indium dopant,
a tin oxide material including an antimony dopant, or
a tin oxide material including a fluorine dopant.

6. The device of claim 1, wherein a thickness of the layer of the quantum dot material is included in a range of approximately 180 nanometers to approximately 220 nanometers.

7. The device of claim 1, wherein the first photodiode is included as part of a system-on-chip integrated circuit device, and
wherein the second photodiode is included as part of an interface structure between the system-on-chip integrated circuit device and an application specific integrated circuit device.

8. A device, comprising:
an array of metal pillar structures; and
a photodiode over contours of the array of metal pillar structures and comprising:
a layer of a first conductive material that conforms to the contours of the array of metal pillar structures;
a layer of a quantum dot material on the layer of the first conductive material; and
a layer of a second conductive material on the layer of quantum dot material.

9. The device of claim 8, wherein the layer of the quantum dot material is a first layer of quantum dot material comprising quantum dots of a first size over contours of a first pair of metal pillar structures, and wherein the device further comprises:
a second layer of a quantum dot material comprising quantum dots of a second size over contours of a second pair of metal pillar structures,
wherein the second size is different from the first size.

10. The device of claim 8, wherein the layer of the first conductive material comprises:
a layer of an oxide material.

11. The device of claim 8, wherein the layer of the second conductive material comprises:
a material that is transmissive to near infrared light waves or short-wave infrared light waves.

12. The device of claim 8, wherein the layer of the quantum dot material comprises:
quantum dots including a lead sulfide core.

13. The device of claim 8, wherein the photodiode is a first photodiode and further comprising:
a second photodiode below the first photodiode.

14. The device of claim 13, wherein the second photodiode comprises:
an organic photodiode configured to detect visible light.

15. A method, comprising:
forming a layer of a first conductive material on a surface;
forming a layer of a quantum dot material on the layer of the first conductive material; and
forming a layer of a second conductive material on the layer of the quantum dot material,
wherein the second conductive material is transmissive to near infrared light or to short-wave infrared light.

16. The method of claim 15, wherein forming the layer of the quantum dot material comprises:
forming the layer of the quantum dot material using an atomic layer deposition process, or
forming the layer of the quantum dot material using a spin coating process.

17. The method of claim 15, wherein forming the layer of the first conductive material on the surface comprises:
forming the layer of the first conductive material along a contour of a metal pillar that is above a deep trench isolation structure included in an optoelectronic device.

18. The method of claim 15, wherein forming the layer of the quantum dot material on the layer of the first conductive material comprises forming a first layer of a first quantum dot material on the layer of the first conductive material and further comprising:
removing portions of the first layer of the first quantum dot material to expose portions of the layer of the first conductive material; and
forming a second layer of a second quantum dot material on the portions of the layer of the first conductive material.

19. The method of claim 15, wherein forming the layer of the first conductive material on the surface comprises:
forming the layer of the first conductive material on a top surface of an application specific integrated circuit device.

20. The method of claim 19, further comprising:
joining the application specific integrated circuit device to a portion of another integrated circuit device using a eutectic bonding process,
wherein the eutectic bonding process joins the layer of the second conductive material to a bottom surface of the portion of the other integrated circuit device.
